(19) United States
(12) Patent Application Publication
(10) Pub. No.: US 2011/0180930 A1
(43) Pub. Date: Jul. 28, 2011

(54) WIRING BOARD, MANUFACTURING METHOD OF THE WIRING BOARD, AND SEMICONDUCTOR PACKAGE

(75) Inventor: Tadashi ARAI, Nagano (JP)

(73) Assignee: SHINKO ELECTRIC INDUSTRIES CO., LTD.

(21) Appl. No.: 12/954,953

(22) Filed: Nov. 29, 2010

(30) Foreign Application Priority Data
Jan. 27, 2010 (JP) 2010-15937

(51) Int. Cl. H01L 23/52; H05K 1/11; H05K 3/10

(52) U.S. Cl. 257/773; 174/264; 29/846; 257/E23.141

(57) ABSTRACT

A wiring board includes a ceramic substrate including a plurality of stacked ceramic layers, an internal wiring, and an electrode electrically connected to the internal wiring, the electrode being exposed from a first surface of the ceramic substrate; and a silicon substrate including a wiring layer, the wiring layer including a wiring pattern and a via-fill, the wiring pattern being formed on a main surface of the silicon substrate, an end of the via-fill being electrically connected to the wiring pattern, another end of the via-fill being exposed from a rear surface of the silicon substrate positioned opposite to the main surface, wherein the another end of the via-fill is bonded to the electrode of the ceramic substrate via a metal layer.

### CROSS-REFERENCE TO RELATED APPLICATIONS

This patent application is based upon and claims the benefit of priority of Japanese Patent Application No. 2010-15937 filed on Jan. 27, 2010 the entire contents of which are incorporated herein by reference.

### BACKGROUND OF THE INVENTION

1. Field of the Invention

The present invention generally relates to wiring boards, manufacturing methods of the wiring boards, and semiconductor packages. More specifically, the present invention relates to a wiring board including silicon and ceramic, a manufacturing method of the wiring board, and a semiconductor package.

2. Description of the Related Art

Conventionally, a semiconductor package where a semiconductor chip is mounted on a wiring board via a solder bump or the like is known. In such a semiconductor package, the wiring board works as an interposer configured to connect the semiconductor chip and a mounting board such as a motherboard. An example of a related art semiconductor package having a wiring board as an interposer is discussed with reference to FIG. 1 through FIG. 3.

FIG. 1 is a cross-sectional view of an example of the related art semiconductor package. As shown in FIG. 1, in a semiconductor package 500, a semiconductor chip 200 is mounted on a substantially center part of a wiring board 100 via solder bumps 300 and is sealed by underfill resin 400.

The wiring board 100 has a structure of a first wiring layer 110, a first insulation layer 140, a second wiring layer 120, a second insulation layer 150, a third wiring layer 130 and a solder resist layer 160. The first wiring layer 110 and the second wiring layer 120 are electrically connected to each other via first via holes 140x provided in the first insulation layer 140. The second wiring layer 120 and the third wiring layer 130 are electrically connected to each other via second via holes 150x provided in the second insulation layer 150.

External connecting terminals 170 such as solder balls are formed on the third wiring layer 130 exposed in opening parts 160x of the solder resist layer 160. The first wiring layer 110 works as electrode pads to be connected to electrode pads 220 of the semiconductor chip 200. The external connecting terminals 170 work as terminals to be connected to the mounting board such as the motherboard. It is general practice that the wiring board 100 has, due to limitations of a wiring width, a diameter of the via hole, and other factors, a multi-layer structure.

The semiconductor chip 200 includes a semiconductor substrate 210 and the electrode pads 220. The semiconductor substrate 210 has a structure where a semiconductor integrated circuit (not illustrated in FIG. 1) is formed on the substrate 210 made of, for example silicon (Si). The electrode pads 220 are formed on one side of the semiconductor substrate 210 and electrically connected to the semiconductor integrated circuit (not illustrated in FIG. 1).

The first wiring layer 110 of the wiring board 100 and the electrode pads 220 of the semiconductor chip 200 are electrically connected to each other via the solder bumps 300. The underfill resin 400 is supplied between a surface of the semiconductor chip 200 and a surface of the wiring board 100, the surfaces facing each other.

Next, a manufacturing method of the related art semiconductor package is discussed. FIG. 2 and FIG. 3 are views of examples of manufacturing steps of the related art semiconductor package. In FIG. 2 and FIG. 3, parts that are the same as the parts shown in FIG. 1 are given the same reference numerals, and explanation thereof is omitted.

First, in a step illustrated in FIG. 2, the wiring board 100 and the semiconductor chip 200 manufactured by known methods are provided. A pre-solder 410 is formed on the first wiring layer 110 of the wiring board 100. A pre-solder 420 is formed on the electrode pads 220 of the semiconductor chip 200.

Next, in a step illustrated in FIG. 3, the first wiring layer 110 side of the wiring board 100 and the electrode pad 220 side of the semiconductor chip 200 are made to face each other so that the pre-solders 410 and 420 are positioned so as to face each other. Then, the pre-solders 410 and 420 are heated at, for example, approximately 230° C. so that the solders are melted and thereby the solder bumps 300 are formed.

Next, the underfill resin 400 is supplied between the surfaces facing each other of the semiconductor chip 200 and the wiring board 100 in a structural body illustrated at a lower side in FIG. 3, so that the semiconductor package 500 including the semiconductor chip 200 illustrated in FIG. 1 is completed. Since a warp may be formed at the wiring board 100 due to shrinkage on curing of the underfill resin 400, it is necessary for the wiring board 100 to have thickness greater than a certain thickness.

The semiconductor package 500 is connected to the mounting board such as the motherboard via the external connecting terminals 170. Thus, in the semiconductor package 500, the wiring board 100 works as an interposer configured to connect the semiconductor chip 200 and the mounting board such as the motherboard. See Japanese National Publication of International Patent Application No. 2003-503855.

However, in the development of down-sizing, miniaturization of the semiconductor chips is continuing. Therefore, minute wiring is required for the interposer where the semiconductor chip is mounted. Therefore, it becomes difficult to respond to the minute wiring required for the interposer by using the related art wiring board illustrated in FIG. 1. Because of this, although the interposers having a silicon base multi-layer structure which can correspond to the minute wiring are being studied, the cost of manufacturing equipment for achieving the required multi-layer structure is increasing so that the manufacturing cost is increased.

### SUMMARY OF THE INVENTION

Accordingly, embodiments of the present invention may provide a novel and useful wiring board, a manufacturing method of the wiring board, and a semiconductor package solving one or more of the problems discussed above.

More specifically, the embodiments of the present invention may provide a wiring board which can prevent increase of the manufacturing cost and correspond to minute wiring, a manufacturing method of the wiring board, and a semiconductor package.

Another aspect of the embodiments of the present invention may be to provide a wiring board, including a ceramic substrate including a plurality of stacked ceramic layers, an internal wiring, and an electrode electrically connected to the internal wiring, the electrode being exposed from a first surface of the ceramic substrate; and a silicon substrate including a wiring layer, the wiring layer including a wiring pattern and a via-fill, the wiring pattern being formed on a main surface of the silicon substrate, an end of the via-fill being electrically connected to the wiring pattern, another end of the via-fill being exposed from a rear surface of the silicon substrate positioned opposite to the main surface, wherein the another end of the via-fill is bonded to the electrode of the ceramic substrate via a metal layer.

Another aspect of the embodiments of the present invention may be to provide a manufacturing method of a wiring board, including a first step of forming a first metal layer on a first surface of a ceramic substrate, the ceramic substrate having a plurality of stacked ceramic layers, an internal wiring, and an electrode electrically connected to the internal wiring, the electrode exposed from the first surface of the ceramic substrate; a second step of forming a second metal layer at a silicon substrate, the silicon substrate including a wiring layer, the wiring layer including a wiring pattern and a via-fill, the wiring pattern being formed on a main surface of the silicon substrate, an end of the via-fill being electrically connected to the wiring pattern, another end of the via-fill being exposed from a rear surface of the silicon substrate positioned opposite to the main surface, the second metal layer being formed on the another end of the via-fill; and a third step of electrically connecting the electrode and the another end of the via-fill by bonding the first metal layer and the second metal layer.

Another aspect of the embodiments of the present invention may be to provide a semiconductor package, including the above-mentioned wiring board as claimed in claim; and a semiconductor chip mounted on the main surface of the silicon substrate of the wiring board.

Additional objects and advantages of the embodiments are set forth in part in the description which follows, and in part will become obvious from the description, or may be learned by practice of the invention. The object and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a cross-sectional view of an example of a related art semiconductor package;

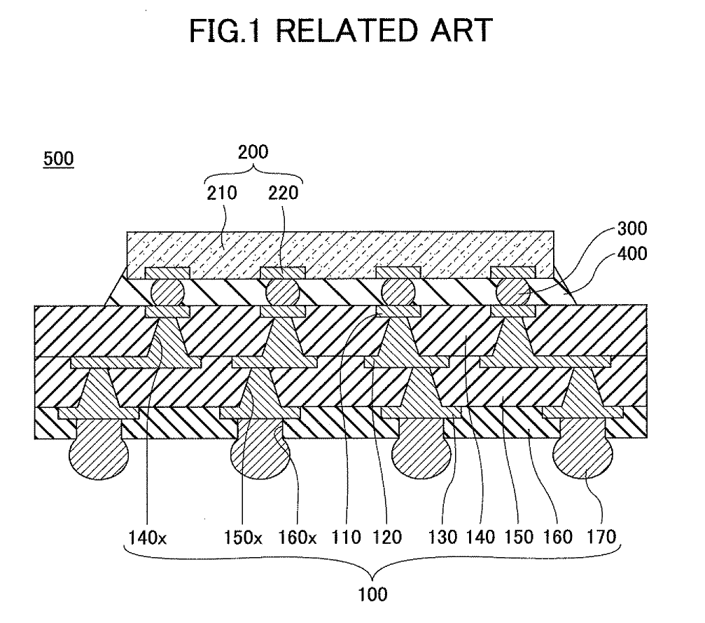

FIG. 2 is a first view of an example of manufacturing steps of the related art semiconductor package;

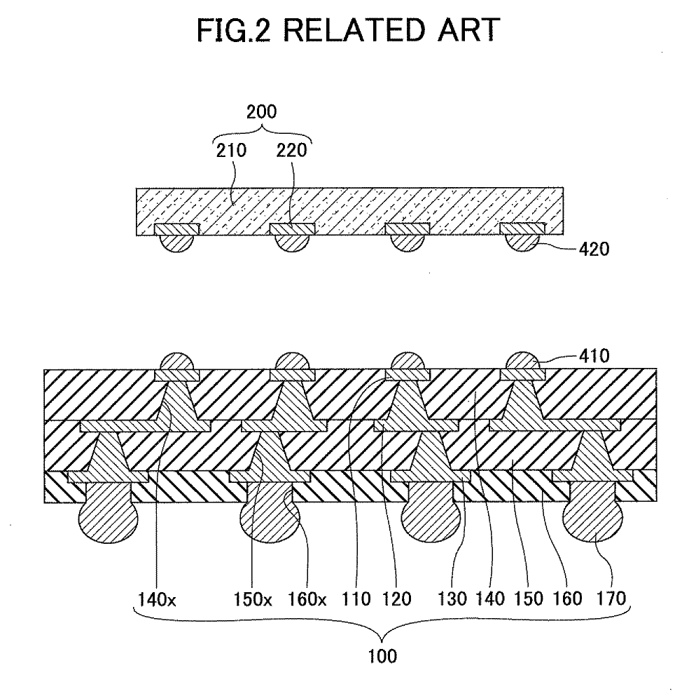

FIG. 3 is a second view of then example of the manufacturing steps of the related art semiconductor package;

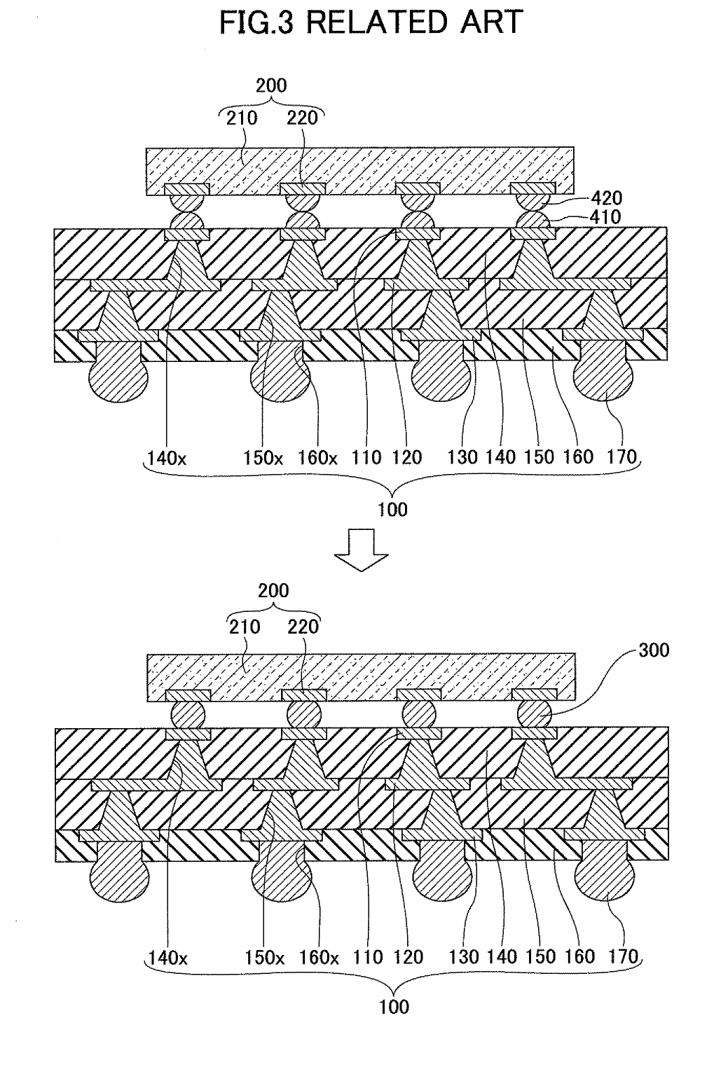

FIG. 4 is a cross-sectional view of an example of a wiring board of a first embodiment of the present invention;

FIG. 5 is a cross-sectional view where an A-part in FIG. 4 is expanded;

FIG. 6 is a first view of an example of manufacturing steps of the wiring board of the first embodiment of the present invention;

FIG. 7 is a second view of the example of the manufacturing steps of the wiring board of the first embodiment of the present invention;

FIG. 8 is a third view of the example of the manufacturing steps of the wiring board of the first embodiment of the present invention;

FIG. 9 is a fourth view of the example of the manufacturing steps of the wiring board of the first embodiment of the present invention;

FIG. 10 is a fifth view of the example of the manufacturing steps of the wiring board of the first embodiment of the present invention;

FIG. 11 is a sixth view of the example of the manufacturing steps of the wiring board of the first embodiment of the present invention;

FIG. 12 is a seventh view of the example of the manufacturing steps of the wiring board of the first embodiment of the present invention;

FIG. 13 is an eighth view of the example of the manufacturing steps of the wiring board of the first embodiment of the present invention;

FIG. 14 is a ninth view of the example of the manufacturing steps of the wiring board of the first embodiment of the present invention;

FIG. 15 is a tenth view of the example of the manufacturing steps of the wiring board of the first embodiment of the present invention;

FIG. 16 is an eleventh view of the example of the manufacturing steps of the wiring board of the first embodiment of the present invention;

FIG. 17 is a twelfth view of the example of the manufacturing steps of the wiring board of the first embodiment of the present invention;

FIG. 18 is a thirteenth view of the example of the manufacturing steps of the wiring board of the first embodiment of the present invention;

FIG. 19 is a fourteenth view of the example of the manufacturing steps of the wiring board of the first embodiment of the present invention;

FIG. 20 is a cross-sectional view of an example of a wiring board of a second embodiment of the present invention;

FIG. 21 is a cross-sectional view where a C-part in FIG. 20 is expanded;

FIG. 22 is a first view of an example of manufacturing steps of the wiring board of the second embodiment of the present invention;

FIG. 23 is a second view of the example of the manufacturing steps of the wiring board of the second embodiment of the present invention;

FIG. 24 is a cross-sectional view of an example of a wiring board of a third embodiment of the present invention;

FIG. 25 is a cross-sectional view where an E-part in FIG. 24 is expanded;

FIG. 26 is a first view of an example of manufacturing steps of a wiring board of a third embodiment of the present invention;

FIG. 27 is a second view of the example of the manufacturing steps of the wiring board of the third embodiment of the present invention;

FIG. 28 is a first view of an example of manufacturing steps of a wiring board of a fourth embodiment of the present invention;

FIG. 29 is a second view of the example of the manufacturing steps of the wiring board of the fourth embodiment of the present invention;

FIG. 30 is a third view of the example of the manufacturing steps of the wiring board of the fourth embodiment of the present invention;

FIG. 31 is a fourth view of the example of the manufacturing steps of the wiring board of the fourth embodiment of the present invention;

FIG. 32 is a first view of an example of manufacturing steps of a wiring board of a fifth embodiment of the present invention;

FIG. 33 is a second view of the example of the manufacturing steps of the wiring board of the fifth embodiment of the present invention;

FIG. 34 is a third view of the example of the manufacturing steps of the wiring board of the fifth embodiment of the present invention;

FIG. 35 is a cross-sectional view of an example of a semiconductor package of a sixth embodiment of the present invention;

FIG. 36 is a first view of an example of manufacturing steps of the semiconductor package of the sixth embodiment of the present invention;

FIG. 37 is a second view of an example of manufacturing steps of the semiconductor package of the sixth embodiment of the present invention;

FIG. 38 is a cross-sectional view of a first modified example of a wiring board of the sixth embodiment of the present invention;

FIG. 39 is a cross-sectional view of a second modified example of a wiring board of the sixth embodiment of the present invention; and

FIG. 40 is a cross-sectional view of a third modified example of a wiring board of the sixth embodiment of the present invention.

### DETAILED DESCRIPTION OF THE PREFERRED EMBODIMENTS

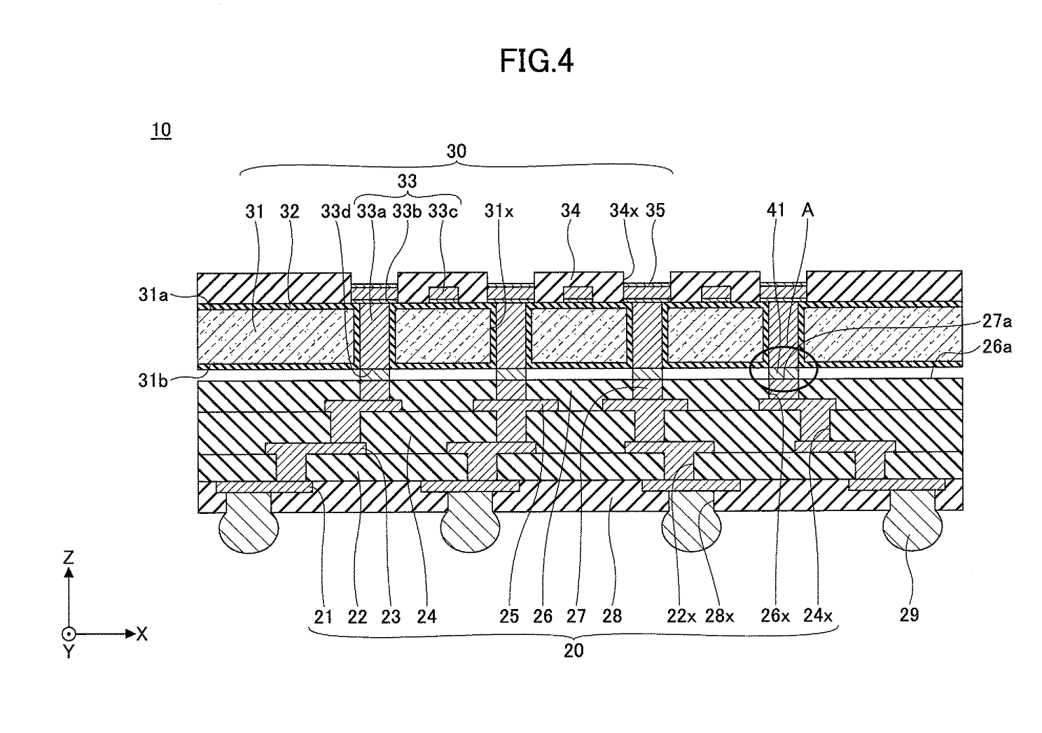

A description is given below, with reference to the FIG. 4 through FIG. 40 of embodiments of the present invention.

### First Embodiment

### Structure of Wiring Board of the First Embodiment

FIG. 4 is a cross-sectional view of an example of a wiring board of a first embodiment of the present invention. As shown in FIG. 4, a wiring board 10 has a structure where a silicon substrate 30 is bonded, via a metal layer 41, onto a ceramic substrate 20. External connecting terminals 29 are provided at the ceramic substrate 20. Details of the anodic bonding are discussed below.

The wiring board 10 has, for example, a rectangular-shaped planar configuration whose width (length in an X direction) can be approximately 15 mm and depth (length in a Y direction) can be approximately 15 mm. A thickness (length in a Z direction) of the ceramic substrate 20 can be, for example, approximately 50 μm through approximately 1000 μm. A thickness (length in the Z direction) of the silicon substrate 30 can be, for example, approximately 50 μm through approximately 500 μm. A thickness (length in the Z direction) of the metal layer 41 can be, for example, approximately 2 μm through approximately 10 μm. Details of the ceramic substrate 20, the external connecting terminals 29, the silicon substrate 30, and the metal layer 41 are discussed.

The ceramic substrate 20 includes a first wiring layer 21, a first ceramic layer 22, a second wiring layer 23, a second ceramic layer 24, a third wiring layer 25, a third ceramic layer 26, electrodes 27, and a solder resist layer 28. In the ceramic substrate 20, the first ceramic layer 22, the second ceramic layer 24, and the third ceramic layer 26 are used as insulation layers. The ceramic substrate 20 is a LTCC (Low Temperature Co-fired Ceramic) multi-layer substrate. A HTCC (High Temperature Co-fired Ceramic) multi-layer substrate may be used as the ceramic substrate 20.

In the case of the LTCC compared to the HTCC, it is possible to easily make the substrate thin. In addition, since the LTCC is sintered at a low temperature such as approximately 900° C., it is possible to use a material having a low melting point and high conductivity, such as copper (Cu), silver (Ag), or gold (Au), as a material of the electrode or the wiring layer. Therefore, it is possible to make a wiring resistance low. Furthermore, the LTCC, compared to the HTCC, is weak against acid or alkali and has low rigidity.

In the case of the HTCC compared to the LTCC, it is difficult to make the substrate thin. In addition, since the HTCC is sintered at a high temperature such as approximately 1600° C., it may not be possible to use a material having a low melting point and high conductivity, such as copper (Cu), silver (Ag), or gold (Au), as a material of the electrode or the wiring layer. It is necessary to use a material having a high melting point and low conductivity, such as tungsten or molybdenum. Therefore, it may not be possible to make a wiring resistance low. Furthermore, the HTCC, compared to the LTCC, is strong against acid or alkali and has high rigidity.

Thus, the LTCC and the HTCC have different characteristics from each other. Therefore, depending of the use, a proper one of the LTCC or the HTCC may be selected. In this embodiment, a case where the LTCC is used as the material of the ceramic substrate 20 is discussed.

The first wiring layer 21 is formed on one of surfaces of the first ceramic layer 22. As a material of the first wiring layer 21, for example, copper (Cu) can be used. Alternatively, as the material of the first wiring layer 21, silver (Ag), gold (Au), or the like may be used. The thickness of the first wiring layer 21 can be, for example, approximately 5 μm.

As a material of the first ceramic layer 22, for example, a material where alumina cordierite is added to glass including sodium oxide (Na₂O), aluminum oxide (Al₂O₃), boron oxide (B₂O₃), and silicon dioxide (SiO₂), or the like can be used. The thickness of the first ceramic layer 22 can be, for example, approximately 10 μm.

Here, the cordierite is a composition including magnesium oxide (MgO), aluminum oxide (Al₂O₃), and silicon dioxide (SiO₂). As an example of composition of the cordierite, 2MgO.2Al₂O₃.5SiO₂ can be used. In addition, the alumina cordierite is made by mixing aluminum oxide (Al₂O₃) with the cordierite.

The second wiring layer 23 is formed on another of the surfaces of the first ceramic layer 22. The second wiring layer 23 includes via-fill supplied in first via-holes 22x which pierce the first ceramic layer 22 and expose an upper surface of the first wiring layer 21, and a wiring pattern formed on the first ceramic layer 22. The second wiring layer 23 is electrically connected to the first wiring layer 21 exposed in the first via-holes 22x. As a material of the second wiring layer 23, for example, copper (Cu) can be used. Alternatively, as the material of the second wiring layer 23, silver (Ag), gold (Au), or the like may be used. The thickness of the wiring pattern of the second wiring layer 23 can be, for example, approximately 5 μm.

The second ceramic layer 24 is formed on the first ceramic layer 22 so as to cover the second wiring layer 23. As a material of the second ceramic layer 24, for example, a material where alumina cordierite is added to glass including sodium oxide (Na₂O), aluminum oxide (Al₂O₃), boron oxide (B₂O₃), and silicon dioxide (SiO₂), or the like can be used. The thickness of the second ceramic layer 24 can be, for example, approximately 10 μm.

The third wiring layer 25 is formed on the second ceramic layer 24. The third wiring layer 25 includes via-fill supplied in second via-holes 24x which pierce the second ceramic layer 24 and expose an upper surface of the second wiring layer 23, and a wiring pattern of the second ceramic layer 24. The third wiring layer 25 is electrically connected to the second wiring layer 23 exposed in the second via-holes 24x. As a material of the third wiring layer 25, for example, copper (Cu) can be used. Alternatively, as the material of the third wiring layer 25, silver (Ag), gold (Au), or the like may be used. The thickness of the wiring pattern of the third wiring layer 25 can be, for example, approximately 5 μm.

The third ceramic layer 26 is formed on the second ceramic layer 24 so as to cover the third wiring layer 25. As a material of the third ceramic layer 26, for example, a material where alumina cordierite is added to glass including sodium oxide (Na₂O), aluminum oxide (Al₂O₃), boron oxide (B₂O₃), and silicon dioxide (SiO₂), or the like can be used. The thickness of the third ceramic layer 26 can be, for example, approximately 10 μm.

By changing an amount of added alumina cordierite, CTEs (Coefficient of Thermal Expansion) of the first ceramic layer 22, the second ceramic layer 24, and the third ceramic layer 26 can be adjusted. The technical significance where the CTEs of the first ceramic layer 22, the second ceramic layer 24, and the third ceramic layer 26 are adjusted is discussed below.

The electrodes 27 include via-fill supplied in third via-holes 26x which pierce the third ceramic layer 26 and expose an upper surface of the third wiring layer 25. Surfaces 27a of the electrodes 27 are substantially flush with a surface 26a of the third ceramic layer 26. In other words, the surfaces 27a of the electrodes 27 are exposed from the surface 26a of the third ceramic layer 26. The electrodes 27 are electrically connected to the third wiring layer 25 exposed in the third via-holes 26x. As a material of the electrodes 27, for example, copper (Cu) can be used. Alternatively, as the material of the electrodes 27, silver (Ag), gold (Au), or the like may be used. The thickness of the wiring pattern forming the electrodes 27 can be, for example, approximately 5 μm.

The solder resist layer 28 is provided on the one of the surfaces of the first ceramic layer 22 so as to cover the first wiring layer 21. The solder resist layer 28 includes opening parts 28x so that parts of the first wiring layer 21 are exposed in the opening parts 28x of the solder resist layer 28. As a material of the solder resist layer 28, for example, a photosensitive resin composition including epoxy group resin, imide group resin, or the like can be used. The thickness of the solder resist layer 28 can be, for example, approximately 15 μm.

If necessary, a metal layer or the like may be formed on the first wiring layer 21 exposed in the opening parts 28x. The metal layer may be, for example, an Au layer, a Ni/Au layer where Ni and Au are stacked in this order, or a Ni/Pd/Au layer where Ni, Pd, and Au are stacked in this order.

The outside connection terminals 29 are formed on the first wiring layer 21 exposed in the opening parts 28x of the solder resist layer 28 of the ceramic substrate 20 (on a metal layer or the like in a case where the metal layer or the like is formed on the first wiring layer 21).

In a planar view, the wiring board 10 has a so-called a fan-out structure. In the fan-out structure, a region where the outside connection terminals 29 are formed extends to the periphery of a region where a wiring layer 33 (working as electrode pads to be connected to the semiconductor chip) exposed in opening parts 34x is formed. In other words, the first wiring layer 21 through the third wiring layer 25 are provided so that the outside connection terminals 29 are situated in the periphery of a region where the semiconductor chip is connected.

The pitch of neighboring outside connection terminals 29 can be increased so as to be greater than the pitch (for example, approximately 80 μm) of the electrode pads of the wiring layer 33 exposed in the neighboring opening parts 34x. For example, the pitch of neighboring outside connection terminals 29 can be approximately 400 μm. The wiring board 10, depending on the purpose, may have a fan-in structure.

The outside connection terminals 29 work as terminals electrically connected to pads provided on a mounting board (not illustrated in FIG. 4) such as a motherboard. As the outside connection terminals 29, for example, solder balls or the like can be used. As a material of the solder balls, for example, an alloy including Pb, an alloy of Sn and Cu, an alloy of Sn and Ag, an alloy of Sn, Ag, and Cu, or the like can be used. A lead pin may be used as the outside connection terminal 29.

Although the outside connection terminals 29 are formed in the first embodiment of the present invention, it is not always necessary to form the outside connection terminals 29. In other words, it is sufficient that a part of the first wiring layer 21 be exposed through the solder resist layer 28 so that the outside connection terminals 29 may be formed if necessary.

The silicon substrate 30 includes a substrate main body 31, an insulation layer 32, the wiring layer 33 including a first metal layer 33a and a second metal layer 33b, a guide resist layer 34, and a metal layer 35.

The substrate main body 31 is made of silicon. The thickness of the substrate main body 31 may be, for example, approximately 50 μm through approximately 500 μm. Via-holes 31x pierce the substrate main body 31 from a surface (main surface) 31a of the substrate main body 31 to a surface (rear surface) 31b of the substrate main body 31. The pitch of the neighboring via-holes 31x can be properly selected but can be, for example, approximately 80 μm. The via-hole 31x has, for example, a circular-shaped planar configuration (seen from the surface 31a or 31b side of the substrate main body 31) having a diameter of, for example, approximately 10 μm through approximately 200 μm.

The insulation layer 32 is formed on the surfaces 31a and 31b of the substrate main body 31 and inside surfaces of the via-holes 31x. The insulation layer 32 is a film configured to provide insulation between the substrate main body 31 and the wiring layer 33. As a material of the insulation layer 32, for example, a silicon dioxide (SiO₂) film can be used. The thickness of the insulation layer 32 can be, for example, approximately 1 μm through approximately 2 μm.

The wiring layer 33 includes the first metal layer 33a, the second metal layer 33b, and a third metal layer 33c. The first metal layer 33a is via-fill supplied in the via-holes 31x. The insulation layer 32 is formed on internal surfaces of the via-holes 31x. The second and third metal layers 33b and 33c are wiring patterns formed on the surface 31a of the substrate main body 31 via the insulation layer 32. The wiring layer 33 is mainly made of copper (Cu). The wiring layer 33 is electrically connected to the electrodes 27 of the ceramic substrate 20 via the metal layer 41.

In this embodiment, a diameter of the via-hole 31x is greater than a diameter of the surface 27a of the electrode 27, so that a diameter of the surface 33d of the wiring layer (a bottom surface of the first metal layer 33a supplied in the via-hole 31x) is substantially equal to the diameter of the surface 27a of the electrode 27. In addition, a center axis of the via hole 31x is consistent with a center axis of the surface 27a of the electrode 27. However, the present invention is not limited to this structure.

Since the wiring layer 33 can be formed on the substrate main body 31 made of silicon by a semiconductor process, a hyperfine via-hole and a hyperfine wiring pattern can be formed. The wiring pattern (the second metal layer 33b and the third metal layer 33c) of the wiring layer 33 can have line/space ratios, for example, equal to approximately 1/1 μm through approximately 10/10 μm. The thickness of the wiring pattern (the second metal layer 33b and the third metal layer 33c) of the wiring layer 33 can be, for example, approximately 1 μm through approximately 10 μm (in the case where the line/space ratio is equal to approximately 1/1 μm through approximately 10/10 μm).

The guide resist layer 34 is formed on the insulation layer 32 formed on the surface 31a of the substrate main body 31 so as to cover the wiring layer 33. The guide resist layer 34 includes opening parts 34x. Parts of the wiring layer 33 are exposed in the opening parts 34x of the guide resist layer 34. The parts of the wiring layer 33 exposed in the opening parts 34x work as electrode pads to be connected to the semiconductor chip. Alternatively, as a material of the guide resist layer 34, insulation resin such as benzocyclobutene (BCB), polybenzoxazole (PBO), or polyimide (PI) can be used. As a material of the guide resist layer 34, for example, a photosensitive resin composition including epoxy group resin, imide group resin, or the like can be used. The thickness of the guide resist layer 28 can be, for example, approximately 5 μm through approximately 30 μm.

The metal layer 35 is formed on the wiring layer 33 exposed in the opening parts 34x of the guide resist layer 34. The metal layer 35 is provided so that connection reliability is improved at the time when the wiring layer 33 exposed in the opening parts 34x is connected to the semiconductor chip. Accordingly, it may not be necessary to provide the metal layer 35 on the wiring layer 33 covered with the guide resist layer 34. The metal layer 35 may be, for example, an Au layer, a Ni/Au layer where Ni and Au are stacked in this order, or a Ni/Pd/Au layer where Ni, Pd, and Au are stacked in this order. In addition, solder plating such as SnAg or SnAgCu can be used as the metal layer 35. However, depending on necessity, it is not necessary to provide the metal layer 35 on the wiring layer 33 exposed in the opening parts 34x of the guide resist layer 34.

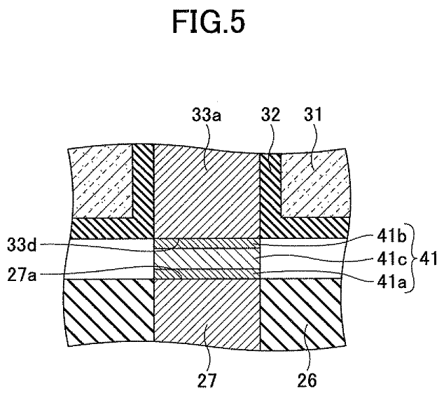

The metal layer 41 electrically connects the electrode 27 of the ceramic substrate 20 and the wiring layer 33 of the silicon substrate 30. FIG. 5 is a cross-sectional view where an A-part in FIG. 4 is expanded. In FIG. 5, parts that are the same as the parts shown in FIG. 4 are given the same reference numerals, and explanation thereof is omitted. As illustrated in FIG. 5, the metal layer 41 includes a first metal layer 41a, a second metal layer 41b, and a third metal layer 41c. The first metal layer 41a is formed on the surface 27a of the electrode 27 of the ceramic substrate 20. The second metal layer 41b is formed on the surface 33d of the first metal layer 33a forming the wiring layer 33 of the silicon substrate 30. The third metal layer 41c is formed between the first metal layer 41a and the second metal layer 41b.

The first metal layer 41a and the second metal layer 41b may each be, for example, a nickel (Ni) layer. The third metal layer 41c may be, for example, an AuSn layer which is a eutectic alloy layer which is made by eutectic reaction of gold (Au) and tin (Sn). However, the third metal layer 41c is not limited to an AuSn layer, as long as the third metal layer 41c is a eutectic alloy layer which is made by eutectic reaction of metal. For example, the third metal layer 41c may be an SnAg layer which is a eutectic alloy layer which is made by eutectic reaction of silver (Ag) and tin (Sn).

It is called “metal bonding” where, as discussed above, the electrode 27 of the ceramic substrate 20 and the wiring layer 33 of the silicon substrate 30 are bonded to each other via a designated metal layer (the metal layer 41 in this embodiment).

The wiring board 10 works as an interposer configured to connect the semiconductor chip (not illustrated in FIG. 4) and the mounting board such as the motherboard (not illustrated in FIG. 4). In the meantime, a CTE (coefficient of thermal expansion) of the silicon substrate is approximately 3 ppm/° C. In addition, a CTE of the semiconductor chip to be connected to the silicon substrate is also approximately 3 ppm/° C., in a case where the semiconductor chip is made of silicon. Thus, the CTEs of the semiconductor chip and the silicon substrate are consistent with each other. Therefore, even if heating is applied at the time when the semiconductor chip and the silicon substrate are connected, it is difficult to generate thermal stress, due to a difference of the CTEs between the semiconductor chip and the silicon substrate 30, at the connecting part of the semiconductor chip and the silicon substrate 30. Because of this, it is possible to improve connection reliability of the semiconductor chip and the silicon substrate 30.

On the other hand, since the metal layer 41 is provided between the ceramic substrate 20 and the silicon substrate 30, it is not necessary that the CTE of the ceramic substrate 20 be equal to the CTE (approximately 3 ppm/° C.) of the silicon substrate 30. Even if heat is applied when the ceramic substrate 20 and the silicon substrate 30 are connected, the metal layer 41 absorbs thermal stress due to the difference of the CTEs. Therefore, the thermal stress may not be generated at a connecting part of the ceramic substrate 20 and the silicon substrate 30. Because of this, even if the CTE of the ceramic substrate 20 is not equal to the CTE (approximately 3 ppm/° C.) of the silicon substrate 30, it is possible to secure the connecting reliability of the ceramic substrate 20 and the silicon substrate 30.

There is no problem even if the CTE of the ceramic substrate 20 is not equal to the CTE (approximately 3 ppm/° C.) of the silicon substrate 30. In addition, a CTE of the mounting board, such as a motherboard mainly made of a resin substrate, to be connected to the ceramic substrate 20, is approximately 18 ppm/° C. Therefore, it may be preferable that the CTE of the ceramic substrate 20 provided between the silicon substrate 30 and the mounting board such as a motherboard be between approximately 10 ppm/° C. and approximately 12 ppm/° C. In addition, as discussed above, the CTE of each of the first ceramic layer 22 through the third ceramic layer 26 can be adjusted by changing the added amount of the alumina cordierite.

Thus, by bonding the ceramic substrate 20 and the silicon substrate 30 via the metal layer 41, even if the CTE of the ceramic substrate 20 is not equal to the CTE (approximately 3 ppm/° C.) of the silicon substrate 30, it is possible to secure the connecting reliability of the ceramic substrate 20 and the silicon substrate 30. In addition, by making a value of the CTE of the ceramic substrate 20 close to the CTE (approximately 18 ppm/° C.) of the mounting board such as the motherboard mainly made of the resin board, such as between approximately 10 ppm/° C. and approximately 12 ppm/° C., it is possible to secure the connecting reliability of the ceramic substrate 20 and the mounting board such as the motherboard.

In a case where further improvement of the connecting reliability of the ceramic substrate 20 and the mounting board such as the motherboard is required, the CTEs of portions of the ceramic substrate 20 can be gradually increased as the portions are away from the silicon substrate 30 and closer to the mounting board such as the motherboard. For example, the CTE of the third ceramic layer 26 closest to the silicon substrate 30 may be between approximately 10 ppm/° C., and approximately 12 ppm/° C.; the CTE of the first ceramic layer 22 closest to the mounting board such as the motherboard may be between approximately 15 ppm/° C. and approximately 17 ppm/° C.; and CTE of the second ceramic layer 24 provided between the first ceramic layer 22 and the third ceramic layer 26 may be between approximately 13 ppm/° C. and approximately 14 ppm/° C.

Thus, the CTEs of portions of the ceramic substrate 20 are gradually increased as the portions are farther from the silicon substrate 30 and closer to the mounting board such as the motherboard, so that the CTEs of the mounting board such as the motherboard and the first ceramic layer 22 closest to the mounting board such as the motherboard are consistent with each other. Therefore, even if heating is applied at the time when the mounting board such as the motherboard and the ceramic substrate 20 are connected, it is difficult to generate thermal stress, due to a difference of the CTEs between the mounting board such as the motherboard and the ceramic substrate 20, at the connecting part of the mounting board such as the motherboard and the ceramic substrate 20. Because of this, it is possible to improve connection reliability of the mounting board such as the motherboard and the ceramic substrate 20.

In addition, because of the same reason, it is difficult to generate thermal stress, due to a difference of the CTEs in the ceramic substrate 20. Because of this, it is possible to improve connection reliability of all of the connecting parts.

### Manufacturing Method of the Wiring Board of the First Embodiment

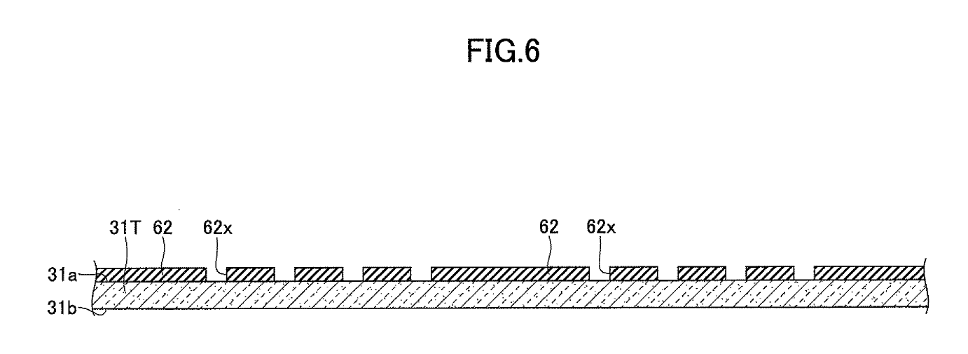

Next, a manufacturing method of the wiring board of the first embodiment is discussed with reference to FIG. 6 through FIG. 19. FIG. 6 through FIG. 19 are views of an example of manufacturing steps of the wiring board of the first embodiment of the present invention. In FIG. 6 through FIG. 19, parts that are the same as the parts shown in FIG. 4 are given the same reference numerals, and explanation thereof is omitted.

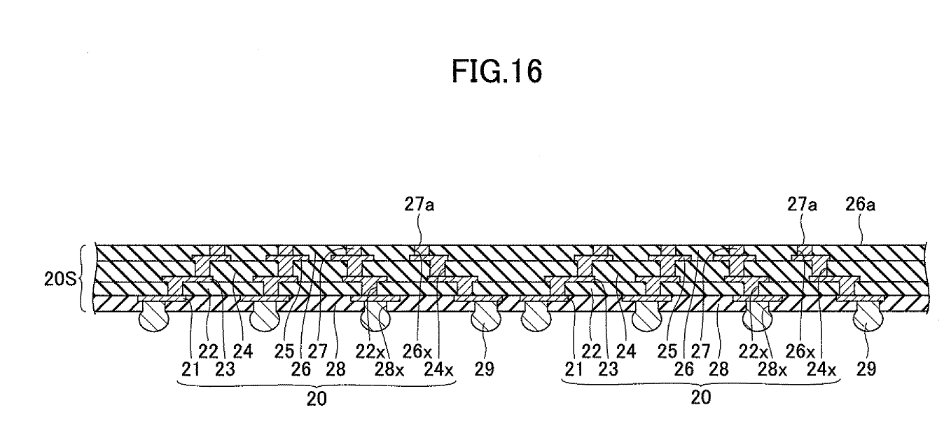

First, in a step illustrated in FIG. 6, a thinned substrate main body 31T is provided. A resist layer 62 having the opening parts 62x corresponding to the electrodes 27 (see FIG. 16) of the ceramic substrate 20S is formed on the surface 31a of the substrate main body 318.

The substrate main body 31T includes plural regions which are finally made into pieces so that the silicon substrates 30 (see FIG. 4) are formed. As the substrate main body 31T, a silicon wafer or the like having a designated thickness or the like can be used. The silicon wafer has, for example, a circular-shaped planar configuration having a diameter of, for example, approximately 6 inches (approximately 150 mm), approximately 8 inches (approximately 200 mm), approximately 12 inches (approximately 300 mm), or the like. A thickness of the substrate main body 31T before being made thin can be, for example, approximately 0.625 mm in the case of the 6-inch wafer, approximately 0.725 mm in the case of the 8-inch wafer, or approximately 0.775 mm in the case of the 12-inch wafer. The thickness of the substrate main body 31T after being made thin can be, for example, approximately 50 μm through approximately 500 μm. For example, a backside grinder or the like can be used for making the substrate main body 31T thin. The planar configuration of the substrate main body 31T may be or may not be circular-shaped. The planar configuration of the substrate main body 31T may be, for example, rectangular-shaped.

In order to form the resist layer 62, liquid or paste resist made of a photosensitive resin composition including, for example, epoxy group resin or imide group resin is applied on the surface 31a of the substrate main body 31T. Alternatively, film resist made of a photosensitive resin composition including, for example, epoxy group resin or imide group resin, is laminated on the surface 31a of the substrate main body 31T. By exposing and developing the applied or laminated resist, the opening parts 62x are formed. As a result of this, the resist layer 62 having the opening parts 62x is formed. A film resist where the opening parts 62x are formed in advance may be laminated on the surface 31a of the substrate main body 31T.

The opening parts 62x are formed in positions corresponding to the electrodes 27. The pitch of the neighboring opening parts 62x may be, for example, approximately 80 μm. The opening part 62x has, for example, a circular-shaped planar configuration having a diameter of, for example, approximately 10 μm through approximately 200 μm. In this embodiment, the diameter of the opening part 62x is greater than the diameter of the surface 27a of the electrode 27.

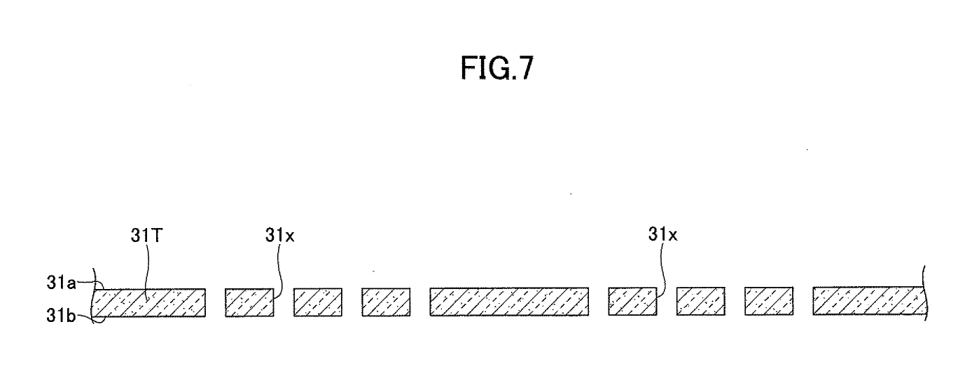

Next, in a step illustrated in FIG. 7, the via-holes 31x piercing between the surfaces 31a and 31b of the substrate main body 31T are formed by etching the substrate main body 31T by using the resist layer 62 illustrated in FIG. 6 as a mask. Then, the resist layer 62 illustrated in FIG. 6 is removed. As a result of this, the via-holes 31x are formed in positions corresponding to the electrodes 27 of the ceramic substrate 20S. The via-holes 31x can be formed by an anisotropic etching method such as the DRIE (Deep Reactive Ion Etching) method using, for example, SF₆. The pitch of the neighboring via-holes 31x corresponds to the pitch of the opening parts 62x and can be, for example, approximately 80 μm. The via-hole 31x has, for example, a circular-shaped planar configuration (seen from the surface 31a or 31b side of the substrate main body 31) having a diameter of, for example, approximately 10 μm through approximately 200 μm, corresponding to the diameter of the opening part 62x.

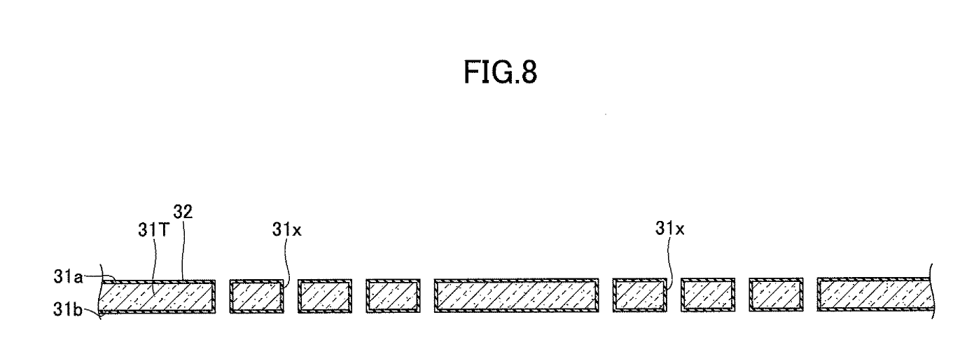

Next, in a step illustrated in FIG. 8, the insulation layer 32 is formed on the surfaces 31a and 31b of the substrate main body 31 and internal surfaces of the via-holes 31x. A silicon dioxide (SiO₂) film can be used as the insulation layer 32. The insulation layer 32 can be formed by thermally deoxidizing with a wet thermal oxidizing method whereby a temperature in the vicinity of the surface of the substrate main body 31T is, for example, equal to or greater than approximately 1000° C. The thickness of the insulation layer 32 can be, for example, approximately 1 μm through approximately 2 μm.

Thus, by forming the insulation layer 32 by the thermal oxidizing method such as the wet thermal oxidizing method compared to by applying an insulation material with a spin coating method or the like, it is possible to simplify manufacturing processes. Hence, it is possible to reduce the manufacturing cost of the wiring board 10. In addition, forming the insulation layer 32 with the wet thermal oxidizing method is more preferable than forming the insulation layer 32 with a dry thermal oxidizing method from the perspective of making the film thick.

In a case where insulation properties are expected to be improved or insertion loss is expected to be reduced, it is preferable to form an insulation layer made of benzocyclobutene (BCB), polybenzoxazole (PBO), polyimide (PI), or the like by the spin coating method or the like. The thickness of the insulation layer made of benzocyclobutene (BCB) or the like by the spin coating method or the like can be, for example, approximately 2 μm through approximately 30 μm which is greater than the insulation layer 32 formed by the thermal oxidizing method. By thickening the insulation layer, it is possible to make a capacitance between the substrate main body 31T and the wiring layer 33 small so that the insertion loss can be reduced.

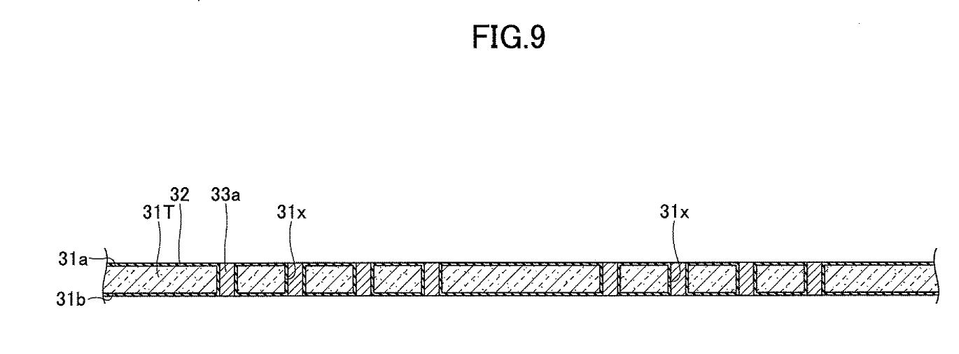

Next, in a step illustrated in FIG. 9, a conductive material is supplied in the via-holes 31x so that the first metal layer 33a is formed. The first metal layer 33a can be formed by deposition growth of a plating film so that the via-holes 31x are filled by an electrolytic plating method where a metal plate is adhered onto one of surfaces of a structural body illustrated in, for example, FIG. 8 and the adhered metal plate is used as a feeding layer. As a material of the first metal layer 33a, for example, copper (Cu) can be used. In addition, a tungsten'paste or the like which is a conductive material may be supplied in the via-holes 31 so that the first metal layer 33a is formed.

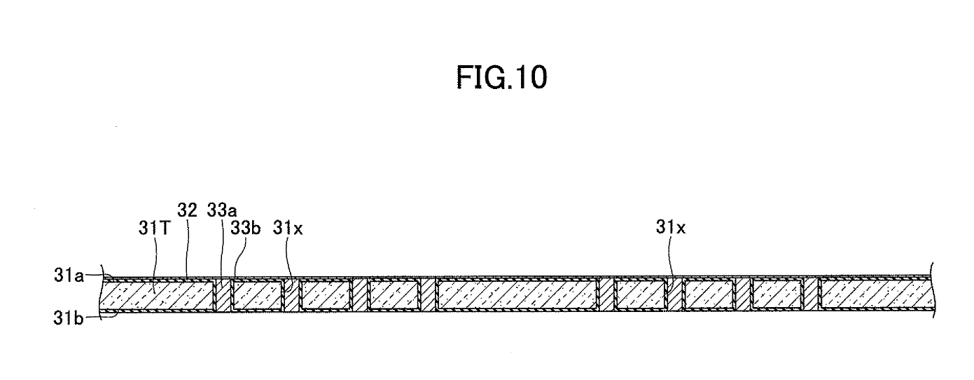

Next, in a step illustrated in FIG. 10, the second metal layer 33b is formed on the insulation layer 32 formed on the surface 31a of the substrate main body 31T and on first metal layer 33a exposed from the insulation layer 32 formed on the surface 31a of the substrate main body 31T. The second metal layer 33b can be formed by, for example, a sputtering method. As the second metal layer 33b, for example, a Ti/Cu layer where Ti and Cu are stacked in this order, a Cr/Cu layer where Cr and Cu are stacked in this order, or the like can be used. In this case, the thickness of the Ti layer can be approximately 0.1 μm through approximately 0.2 μm; the thickness of the Cr layer can be approximately 0.05 μm through approximately 0.1 μm; and the thickness of the Cu layer can be approximately 0.1 μm through approximately 0.5 μm.

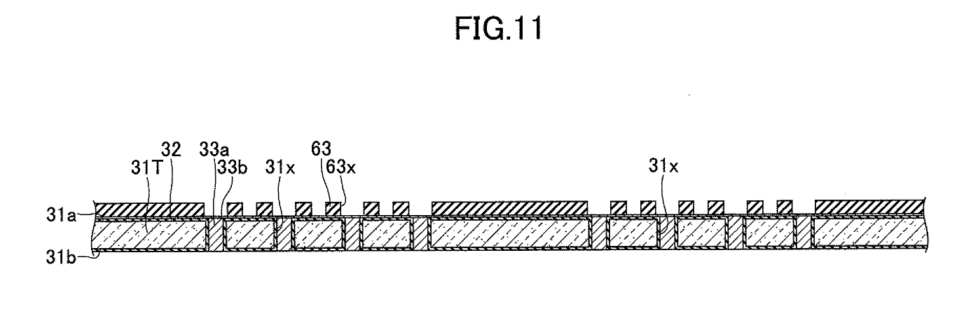

Next, in a step illustrated in FIG. 11, the resist layer 63 having the opening parts 63x corresponding to the third metal layer 33c forming the wiring layer 33 is formed on the second metal layer 33b. More specifically, liquid or paste resist made of photosensitive resin composition including, for example, epoxy group resin or imide group resin, is applied on the second metal layer 33b. Alternatively, film resist made of photosensitive resin composition including, for example, epoxy group resin or imide group resin, is laminated on the second metal layer 33b. By exposing and developing the applied or laminated resist, the opening parts 63x are formed. As a result of this, the resist layer 63 having the opening parts 63x is formed. A film resist where the opening parts 63x are formed in advance may be laminated on the second metal layer 33b.

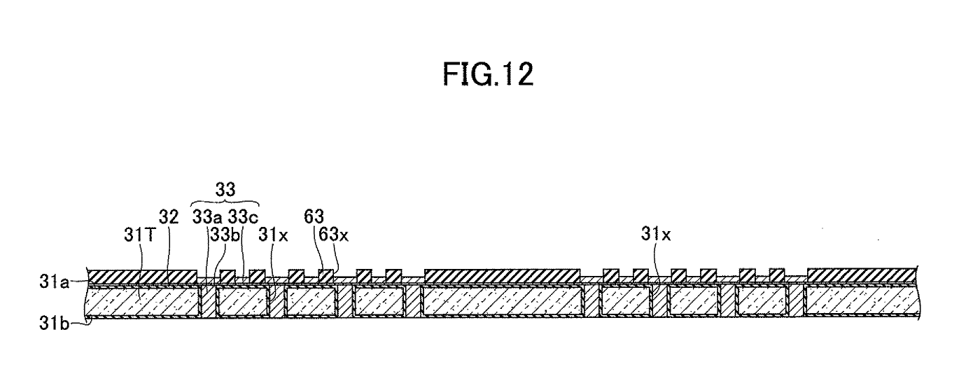

Next, in a step illustrated in FIG. 12, the third metal layer 33c is formed on the second metal layer 33b exposed in the opening parts 63x. The third metal layer 33c can be formed by, for example, the electrolytic plating method where the second metal layer 33b is used as a feeding layer. As the third metal layer 33c, for example, a Cu layer or the like can be used.

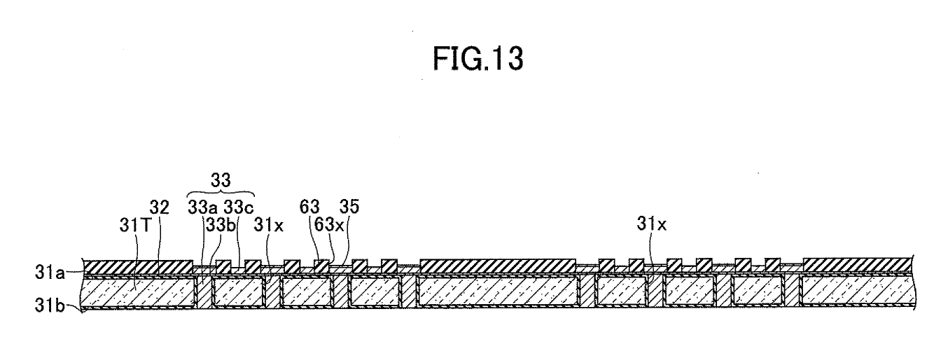

Next, in a step illustrated in FIG. 13, the metal layer 35 is formed on the third metal layer 33c. The metal layer 35 can be formed by, for example, the electrolytic plating method where the second metal layer 33b is used as a feeding layer. The metal layer 35 may be, for example, an Au layer, a Ni/Au layer where Ni and Au are stacked in this order, or a Ni/Pd/Au layer where Ni, Pd, and Au are stacked in this order. In addition, solder plating with such as SnAg or SnAgCu can be used as the metal layer 35. However, depending on necessity, it is not necessary to provide the metal layer 35. The thickness of the metal layer 35 can be, for example, approximately 0.5 μm through approximately 5 μm.

The metal layer 35 is provided so that connection reliability at the time when the wiring layer 33 is connected to the semiconductor chip is improved. Because of this, it is not necessary to form the metal layer 35 on a portion not finally exposed from the guide resist layer 34. Therefore, it may be possible to mask a portion of the wiring layer 33 not finally exposed from the guide resist layer 34 and then to form the metal layer 35, so that the cost of material such as Au forming the metal layer 35 can be reduced.

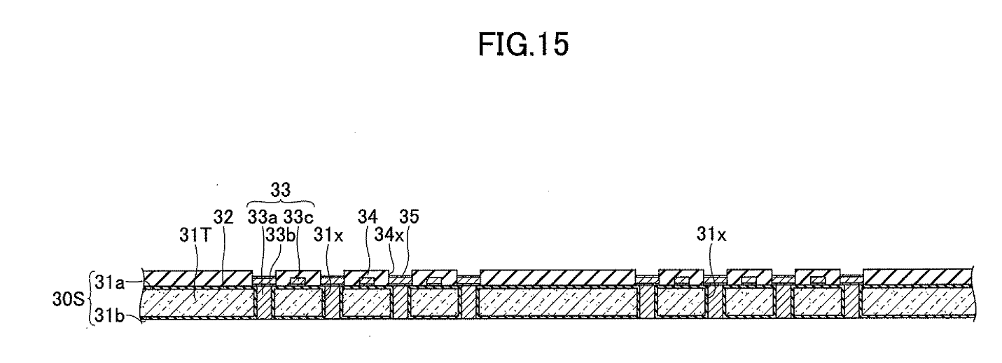

Instead of where the metal layer 35 is formed in the step illustrated in FIG. 13, the metal layer 35 may be formed in a step illustrated in FIG. 15. More specifically, after the guide resist layer 34 having the opening part 34x is formed in the step illustrated in FIG. 15 discussed below, the metal layer 35 may be formed on the third metal layer 33c exposed from the opening part 34x by an electroless plating method.

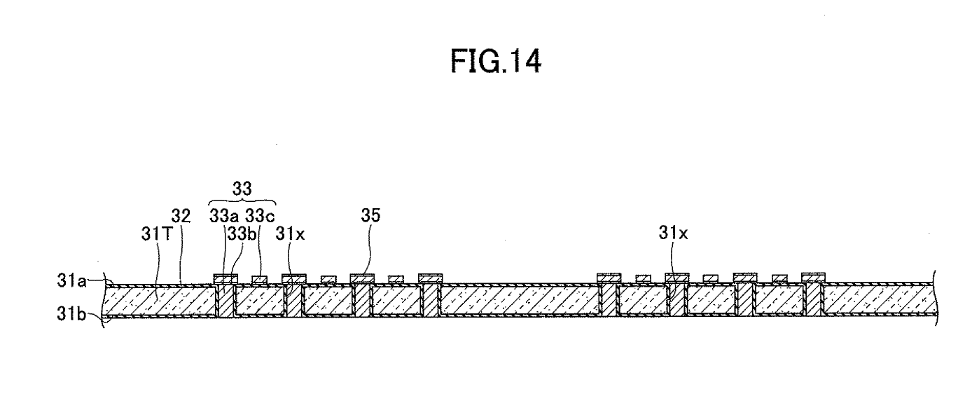

Next, in a step illustrated in FIG. 14, after the resist layer 63 illustrated in FIG. 13 is removed, a portion of the second metal layer 33b not covered with the third metal layer 33c is etched by using the third metal layer 33c as a mask so as to be removed. As a result of this, the wiring layer 33 having the following structure is formed. That is, the wiring layer 33 includes the first metal layer 33a and the second and third metal layers 33b and 33c. The first metal layer 33a is via-fill supplied in the via-holes 31x having the internal surface where insulation layer 32 is formed. The second and third metal layers 33b and 33c are wiring patterns formed on the surface 31a of the substrate main body 31 via the insulation layer 32.

The wiring pattern (the second and third metal layers 33b and 33c) of the wiring layer 33 can have a line/space ratio, for example, equal to approximately 1/1 μm through approximately 10/10 μm. The thickness of the wiring pattern (the second and third metal layers 33b and 33c) of the wiring layer 33 can be, for example, approximately 1 μm through approximately 10 μm (in the case where the line/space ratio is equal to approximately 1/1 μm through approximately 10/10 μm). Thus, the wiring pattern (the second and third metal layers 33b and 33c) of the wiring layer 33 can be formed by a semi-additive method. The wiring pattern (the second and third metal layers 33b and 33c) of the wiring layer 33 may be formed by various kinds of wiring forming methods such as a subtractive method, in addition to the semi-additive method.

Next, in a step illustrated in FIG. 15, the guide resist layer 34 is formed on the insulation layer 32 formed on the surface 31a of the substrate main body 31. The guide resist layer 34 includes the opening parts 34x configured to expose the metal layer 35. More specifically, for example, the mask is provided on the metal layer 35 and the insulation resin, such as benzocyclobutene (BOB), polybenzoxazole (PBO), or polyimide (PI), is applied on the insulation layer 32 formed on the surface 31a of the substrate main body 31S by a spin coating method so as to be cured. The opening parts 34x are formed by removing the mask. As a result of this, the guide resist layer 34 having the opening parts 34x is formed. The metal layer 35 is exposed in the opening parts 34x of the guide resist layer 34. The thickness of the guide resist layer 34 can be, for example, approximately 2 μm through approximately 30 μm.

As a material of the guide resist layer 34, for example, a photosensitive resin composition including epoxy group resin, imide group resin, or the like can be used. In this case, the solder resist made of the photosensitive resin composition including epoxy group resin, imide group resin, or the like is applied on the insulation layer 32 formed on the surface 31a of the substrate main body 31T so as to cover the wiring layer 33 and the metal layer 35. Then, by exposing and developing the applied resist, the opening parts 34x are formed. As a result of this, the resist layer 34 having the opening parts 34x is formed.

A structural body manufactured in the step illustrated in FIG. 15 is called a silicon substrate 30S. The silicon substrate 30S includes plural regions which are finally made into pieces so that the silicon substrates 30 (see FIG. 4) are formed. In addition, the silicon substrate 30S includes only the wiring layer 33 and does not have a multi-layer structure. Therefore, it is possible to inhibit increase of the equipment cost and to manufacture the wiring board at high yield rate. Hence, it is possible to reduce the cost for manufacturing.

Next, in a step illustrated in FIG. 16, a ceramic substrate 20S is manufactured. The ceramic substrate 20S includes plural regions which are finally made into pieces so that the ceramic substrates 20 (see FIG. 4) are formed. The ceramic substrate 20S is a LTCC (Low Temperature Co-fired Ceramic) multi-layer substrate. Although the external connecting terminals 29 are formed at the ceramic substrate 20S, it is not always necessary to form the external connecting terminals 25 at this timing. The external connecting terminals 25 may be formed at a necessary timing.

As a material of each of the ceramic layers of the ceramic substrate 20S, for example, a material where alumina cordierite is added to glass including sodium oxide (Na₂O), aluminum oxide (Al₂O₃), boron oxide (B₂O₃), and silicon dioxide (SiO₂), or the like can be used. The ceramic substrate 20S has, for example, a circular-shaped planar configuration having a diameter of, for example, approximately 6 inches (approximately 150 mm), approximately 8 inches (approximately 200 mm), approximately 12 inches (approximately 300 mm), or the like. The thickness of the ceramic substrate 20S can be, for example, approximately 50 μm through approximately 1000 μm.

The ceramic substrate 20S can be manufactured as follows, for example. First, an organic binder and a solvent are added to a material where powder of the alumina cordierite is added to powder of the glass including sodium oxide (Na₂O), aluminum oxide (Al₂O₃), boron oxide (B₂O₃), and silicon dioxide (SiO₂). Slurry is made by mixing this material, and then a sheet of the slurry is made by a deposition apparatus. The slurry discharged from the deposition apparatus is applied onto a carrier tape and becomes a green sheet after passing a dry zone. After that, the sheet is cut to a designated size. Next, holes which finally become via-holes are formed in the green sheet. After conductive materials which finally become via-fill and wiring patterns are printed, the green sheets are stacked and sintered so that the ceramic substrate 20S is manufactured.

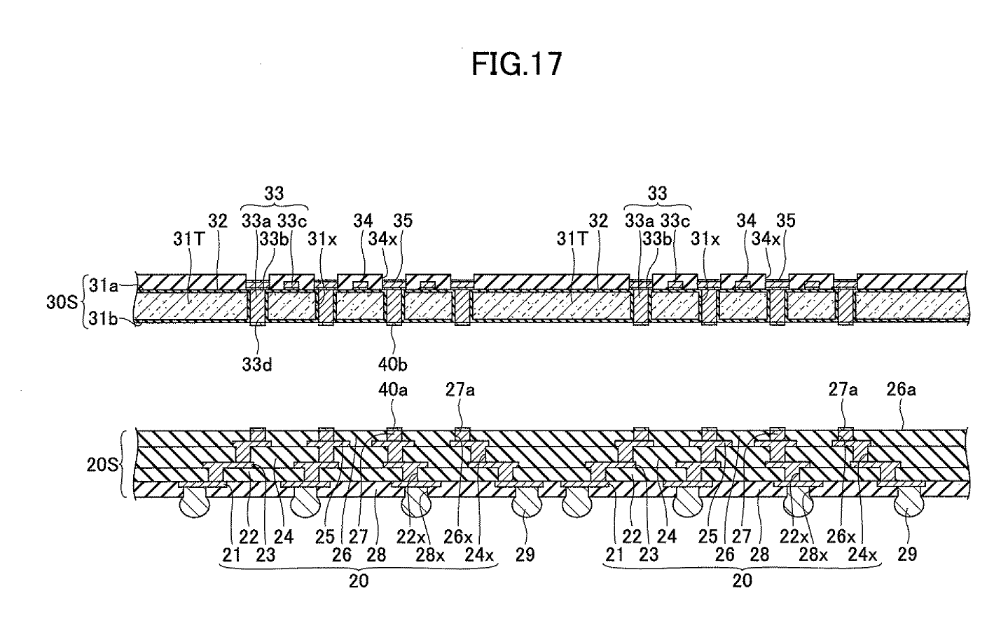

Next, in a step illustrated in FIG. 17, the first metal layer 40a is formed on the surfaces 27a of the electrodes 27 of the ceramic substrate 20. In addition, the second metal layer 40b is formed on the surface 33d of the first metal layer 33a of the silicon substrate 30, namely a bottom surface of the first metal layer 33a supplied in the via-holes 31x. The first metal layer 40a and the second metal layer 40b can be formed by, for example, an electroless plating method or the like. A thickness of each of the first metal layer 40a and the second metal layer 40b can be, for example, between approximately 1 μm and approximately 5 μm.

The first metal layer 40a can be, for example, a Ni/Au layer where nickel (Ni) and gold (Au) are stacked on the surface 27a in this order. The second metal layer 40b can be, for example, a Ni/AuSn layer where a nickel (Ni) layer and an AnSn layer are stacked on the surface 33d in this order. The AuSn layer is a eutectic alloy layer which is made by eutectic reaction of gold (Au) and tin (Sn).

At least one of the first metal layer 40a and the second metal layer 40b may include the eutectic alloy layer which is made by the eutectic reaction of metal. For example, the first metal layer 40a may be a Ni/SnAg layer where a nickel (Ni) layer and an SnAg layer are stacked on the surface 27a in this order. The SnAg layer is a eutectic alloy layer which is made by eutectic reaction of tin (Sn) and silver (Ag). The first metal layer 40a may be a Ni/SnAg layer where a nickel (Ni) layer and an SnAg layer are stacked on the surface 33d in this order. The SnAg layer is a eutectic alloy layer which is made by eutectic reaction of tin (Sn) and silver (Ag).

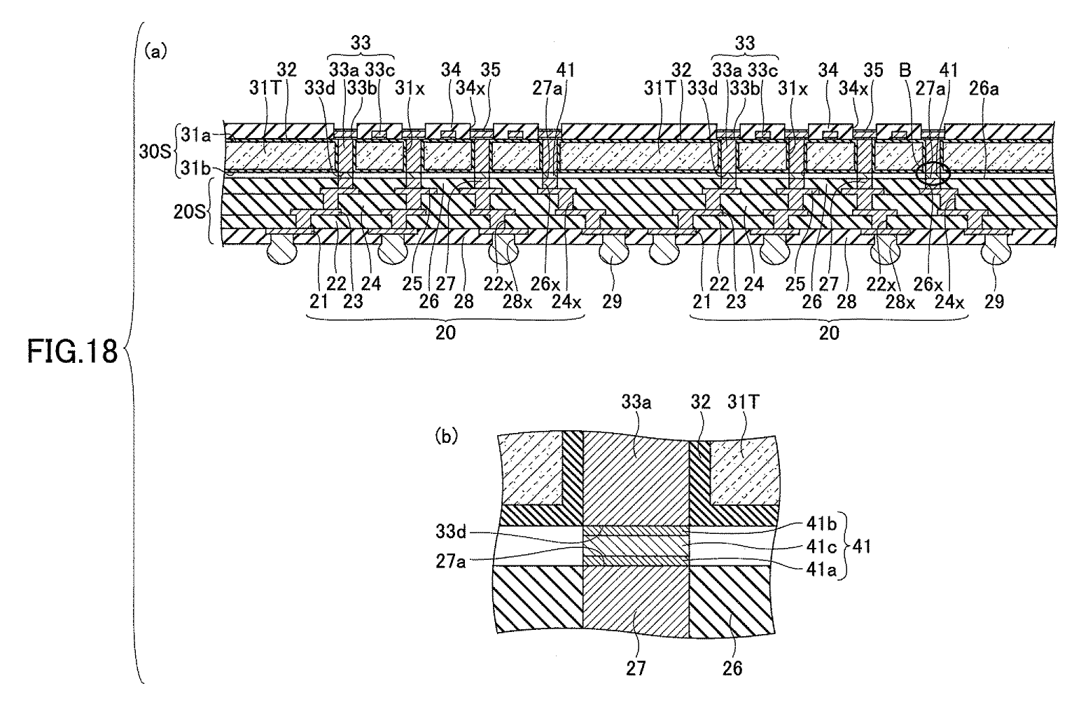

Next, in a step illustrated in FIGS. 18(a)-18(b), the first metal layer 40a formed on the surfaces 27a of the electrodes 27 of the ceramic substrate 20S and the second metal layer 40b formed on the surface 33d of the wiring layer 33 of the silicon substrate 30S are bonded so that the metal layer 41 is formed (eutectic bonding). As a result of this, the ceramic substrate 20S and the silicon substrate 30S are bonded to each other via the metal layer 41. Here, FIG. 18(b) is an expanded cross-sectional view of a B-part in FIG. 18(a).

More specifically, first, the center of the electrode 27 of the ceramic substrate 20S illustrated in FIG. 17 and the center of the via-hole 31x of the silicon substrate 30S are positioned and the first metal layer 40a and the second metal layer 40b come in contact with each other. Pressing at a pressure of, for example, approximately 2 MPa through approximately 8 MPa is applied. While the pressing is applied, the first metal layer 40a and the second metal layer 40b are heated at a temperature of approximately 280° C. through approximately 320° C. where eutectic reaction of gold (Au) and tin (Sn) is generated.

As a result of this, a eutectic reaction of gold (Au) and tin (Sn) is generated so that a new AuSn layer (hereinafter, a third metal layer 41c), where an Au layer forming the first metal layer 40a and an AuSn layer forming the second metal layer 40b are a eutectic alloy, is formed. After that, cooling is applied so that an Ni layer (hereinafter, a first metal layer 41a) forming the first metal layer 40a and an Ni layer (hereinafter, a second metal layer 41b) forming the second metal layer 40b are eutectic-bonded via the newly formed AuSn layer (the third metal layer 41c). As a result of this, the metal layer 41 is formed.

In a case where the Ni/SnAg layer, where the nickel (Ni) layer and the SnAg layer being a eutectic alloy layer which is made by a eutectic reaction of tin (Sn) and silver (Ag) are stacked on the surface 27a in this order, is used as the first metal layer 40a; and the Ni/SnAg layer, where the nickel (Ni) layer and the SnAg layer being a eutectic alloy layer which is made by eutectic reaction of tin (Sn) and silver (Ag) are stacked on the surface 33d in this order, is used as the second metal layer 40b; by heating the first metal layer 40a and the second metal layer 40b at approximately 220° C. through approximately 280° C., a new SnAg layer, where a SnAg layer forming the first metal layer 40a and a SnAg layer forming the second metal layer 40b are eutectic alloys based on the eutectic reaction, is formed. After that, cooling is applied so that the Ni layer forming the first metal layer 40a and the Ni layer forming the second metal layer 40b are eutectic-bonded via the newly formed SnAg layer. As a result of this, the metal layer 41 is formed.

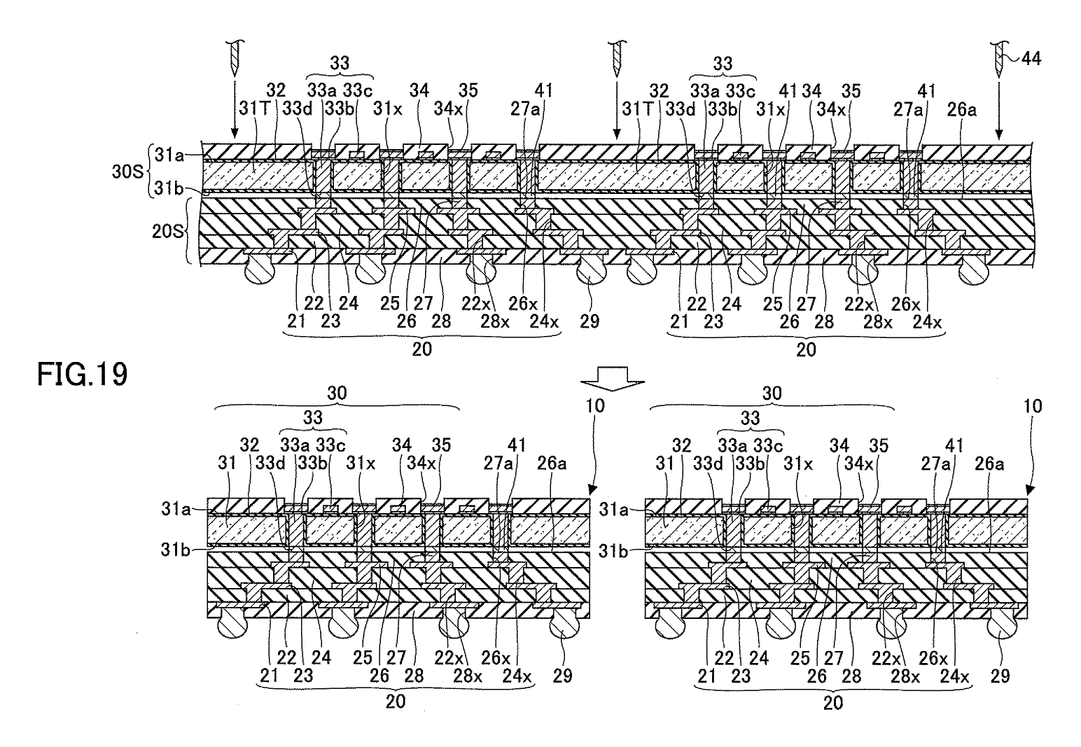

Next, in a step illustrated in FIG. 19, a structural body illustrated in FIG. 18 is cut in designated positions so that the wiring board 10 illustrated in FIG. 4 and including the ceramic substrate 20 and the silicon substrate 30 is completed. The structural body illustrated in FIG. 18 can be cut by dicing using a dicing blade 44 or the like. Here, “the designated positions” means positions for boundaries of plural areas for the ceramic substrates 20 of the ceramic substrate 20S and corresponding positions for boundaries of plural areas for the silicon substrates 30 of the silicon substrate 30S. The substrate main body 31T is cut so that the substrate main bodies 31 are formed.

As discussed above, according to the first embodiment of the present invention, the ceramic substrate and the silicon substrate are provided. The ceramic substrate includes stacked plural ceramic layers and internal wiring. Electrodes electrically connected to the internal wiring are exposed from one surface of the ceramic substrate. A first metal layer is formed on a surface of the electrodes exposed from the one surface of the ceramic substrate. In addition, the silicon substrate includes a wiring layer. The wiring layer includes a wiring pattern formed on the main surface of the silicon substrate and via-fills. One end of the via-fill is electrically connected to the wiring pattern. Another end of the via-fill is exposed from a rear surface which is a surface opposite to a main surface. A second layer is formed on a surface of the via-fills exposed from the rear surface of the silicon substrate. In addition, by eutectically bonding the first metal layer and the second metal layer to each other, the wiring board where the electrodes of the ceramic substrate and the via-fills of the silicon substrate are electrically connected to each other is completed.

As a result of this, it is possible to realize a wiring board having specific features of the silicon substrate where hyperfine via-holes and hyperfine wiring patterns can be formed and specific features of the ceramic substrate where good rigidity and low thermal conductivity are provided, manufacturing cost is low, and a multilayer structure can be formed.

In addition, the silicon substrate includes only the wiring layer and does not have a multi-layer structure. Therefore, it is possible to inhibit increase of the equipment cost and to manufacture the wiring board at a high yield rate. Hence, it is possible to reduce the cost for manufacturing the wiring board including the silicon substrate and the ceramic substrate. Accordingly, by making this wiring board as an interposer for connecting the semiconductor chip and the mounting board such as the motherboard, it is possible to realize the interposer which can correspond to a fine structure of the semiconductor chip at low cost.

In addition, since the ceramic substrate and the silicon substrate are connected to each other by the metal layer, even if the CTE of the ceramic substrate is not equal to the CTE (approximately 3 ppm/° C.) of the silicon substrate, it is possible to secure the connecting reliability of the ceramic substrate and the silicon substrate. In addition, by making a value of the CTE of the ceramic substrate close to the CTE (approximately 18 ppm/° C.) of the mounting board such as the motherboard mainly made of the resin board, such as between approximately 10 ppm/° C. and approximately 12 ppm/° C., it is possible to secure the connecting reliability of the ceramic substrate and the mounting board such as the motherboard when the wiring board functions as the interposer between the semiconductor chip and the mounting board such as the motherboard.

The CTE of the ceramic layer far from the silicon substrate can be close to the CTE of the mounting board such as the motherboard by making the CTE of the ceramic layer far from the silicon substrate greater than the CTE of the ceramic layer close to the silicon substrate. As a result of this, it is difficult to generate thermal stress, due to differences of the CTEs, at the connecting part of the ceramic substrate and the mounting board such as the motherboard. Therefore, it is possible to further improve the connecting reliability of the ceramic substrate and the mounting board such as the motherboard when the wiring board functions as the interposer between the semiconductor chip and the mounting board such as the motherboard.

In addition, when the semiconductor package where the semiconductor chip is mounted on the wiring board of the first embodiment is manufactured, the semiconductor chip is mounted on the silicon substrate. Since the CTEs of the semiconductor chip and the silicon substrate are substantially equal to each other in the case where the semiconductor chip is made of silicon, it is difficult to generate the thermal stress due to the difference of the CTEs at the connecting part of the semiconductor chip and the silicon substrate. As a result of this, since it is possible to sufficiently secure the connecting reliability of the semiconductor chip and the silicon substrate, it may not be necessary to supply the underfill resin between the semiconductor chip and the silicon substrate when the semiconductor package is manufactured.

By forming the insulation layer configured to insulate the substrate main body and the wiring pattern by the thermal oxidizing method such as the wet thermal oxidizing method compared to by applying an insulation material with a spin coating method or the like, it is possible to simplify manufacturing processes. Hence, it is possible to reduce the manufacturing cost of the wiring board.

### Second Embodiment

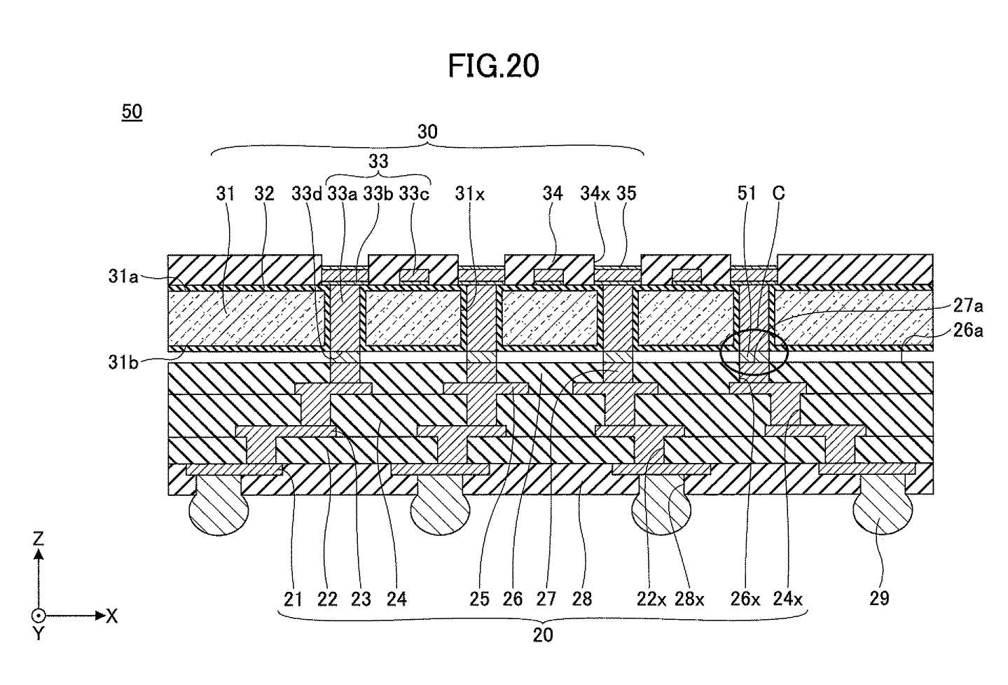

In the first embodiment, an example where the metal layer 41 of the wiring board 10 illustrated in FIG. 4 is formed by a eutectic reaction, which is one example of metal bonding, is discussed. In a second embodiment, an example where a metal layer 51 of a wiring board 50 illustrated in FIG. 20 is formed by solid phase-liquid phase bonding (TLP bonding: Transient Liquid Phase bonding) which is another example of the metal bonding is discussed.

### Structure of Wiring Board of the Second Embodiment

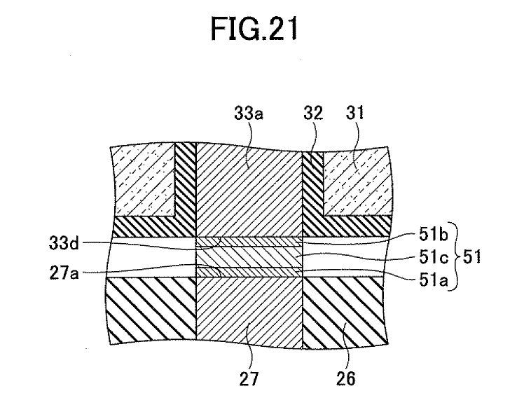

FIG. 20 is a cross-sectional view of an example of a wiring board of a second embodiment of the present invention. FIG. 21 is a cross-sectional view where a C-part in FIG. 20 is expanded. In FIG. 21, parts that are the same as the parts shown in FIG. 20 are given the same reference numerals, and explanation thereof is omitted. As illustrated in FIG. 20 and FIG. 21, the wiring board 50 is different from the wiring board 10 illustrated in FIG. 4 and FIG. 5 in that the metal layer 41 is replaced with the metal layer 51.

The metal layer 51 of the wiring board 50 includes a first metal layer 51a, a second metal layer 51b, and a third metal layer 51c. The first metal layer 51a is formed on the surface 27a of the electrode 27 of the ceramic substrate 20. The second metal layer 51b is formed on the surface 33d of the first metal layer 33a forming the wiring layer 33 of the silicon substrate 30. The third metal layer 51c is formed between the first metal layer 51a and the second metal layer 51b.

The first metal layer 51a and the second metal layer 51b can be, for example, a nickel (Ni) layer. The third metal layer 51c can be, for example, an AuIn layer made of an alloy of gold (Au) and indium (In). The second metal layer 51b may be an Ni/Pd layer where a nickel (Ni) layer and a palladium (Pd) layer are stacked on the surface 33d in this order.

### Manufacturing Method of the Wiring Board of the Second Embodiment

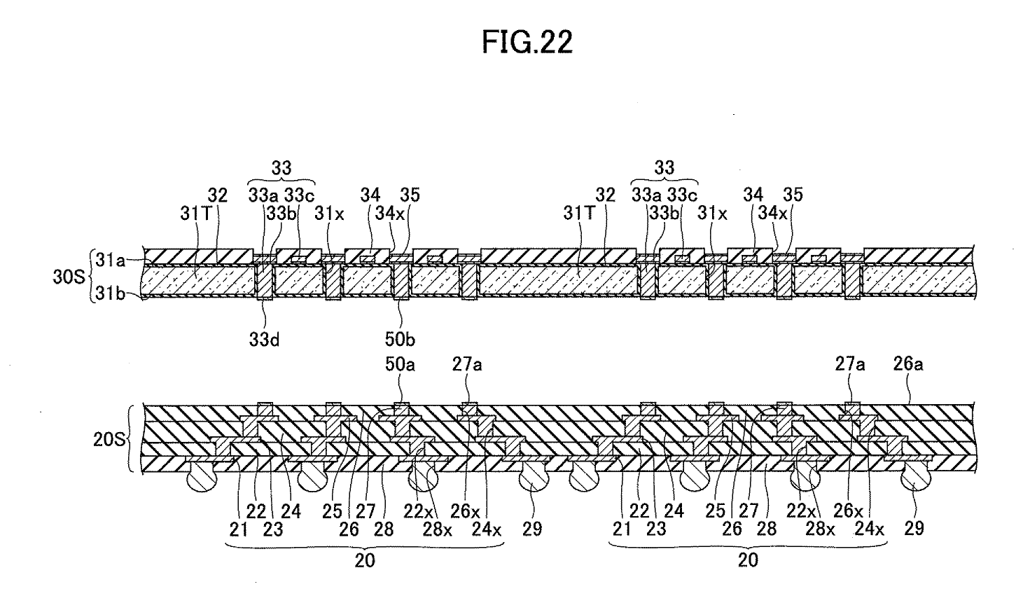

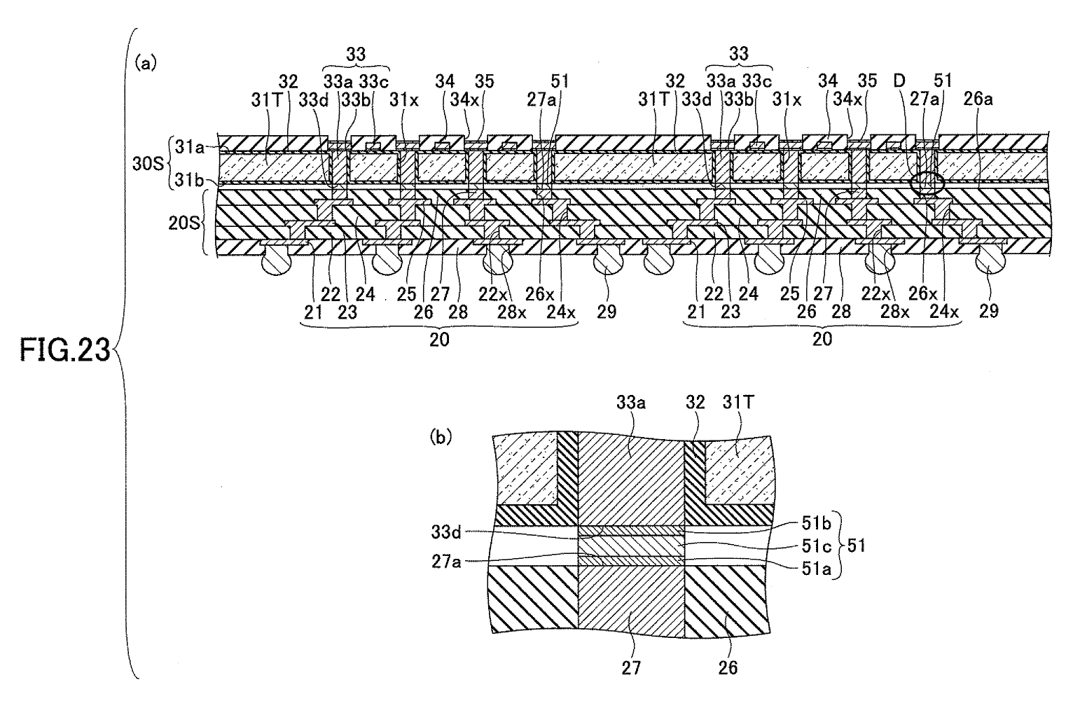

Next, a manufacturing method of the wiring board of the second embodiment is discussed with reference to FIG. 22 and FIG. 23.

FIG. 22 is a first view of an example of manufacturing steps of the wiring board of the second embodiment of the present invention. FIG. 23 is a second view of the example of the manufacturing steps of the wiring board of the second embodiment of the present invention. In FIG. 22 and FIG. 23, parts that are the same as the parts shown in FIG. 20 are given the same reference numerals, and explanation thereof is omitted.

In the embodiment, as well as the first embodiment, first, the same steps as steps illustrated in FIG. 6 through FIG. 16 are performed. Next, in a step illustrated in FIG. 22, a first metal layer 50a is formed on the surfaces 27a of the electrodes 27 of a ceramic substrate 20S. In addition, a second metal layer 50b is formed on the surface 33d of the wiring layer 33 of the silicon substrate 30S (a bottom surface of the first metal layer 33a supplied in the via holes 31x).

The first metal layer 50a may be, for example, a Ni/Au/In layer where nickel (Ni), gold (Au), and indium (In) are stacked on the surface 27a in this order. The second metal layer 50b may be, for example, a Ni/Au layer where nickel (Ni) and gold (Au) are stacked on the surface 33d in this order. The second metal layer 50b may be a Ni/Pd/Au layer where nickel (Ni), palladium (Pd) and gold (Au) are stacked on the surface 33d in this order. The first metal layer 50a and the second metal layer 50b can be formed by, for example, an electroless plating method or the like. A thickness of each of the first metal layer 50a and the second metal layer 50b can be, for example, between approximately 1 μm and approximately 5 μm.

Next, in a step illustrated in FIGS. 23(a)-23(b), the first metal layer 50a formed on the surfaces 27a of the electrodes 27 of the ceramic substrate 20S and the second metal layer 50b formed on the surface 33d of the wiring layer 33 of the silicon substrate 30S are bonded, so that the metal layer 51 is formed (solid phase—liquid phase bonding). As a result of this, the ceramic substrate 20S and the silicon substrate 30S are bonded to each other via the metal layer 51. Here, FIG. 23(b) is an expanded cross-sectional view of a D-part illustrated in FIG. 23(a).

More specifically, first, the center of the electrode 27 of the ceramic substrate 20S illustrated in FIG. 22 and the center of the via-hole 31x of the silicon substrate 30S are positioned and the first metal layer 50a and the second metal layer 50b come in contact with each other. Pressing at a pressure of, for example, approximately 2 MPa through approximately 8 MPa is applied. While the pressing is applied, the first metal layer 50a and the second metal layer 50b are heated at a temperature of approximately 180° C. through approximately 220° C. where only the indium (In) layer forming the first metal layer 50a is melted so as to be in the liquid phase.

As a result of this, only the indium (In) layer forming the first metal layer 50a is melted so as to be in the liquid phase. The liquid phase indium (In) layer is diffused to the gold (Au) layer forming the first metal layer 50a and the gold (Au) layer forming the second metal layer 50b which are in the solid phase. Indium is solidified in a state where the melting point becomes high, so that an AuIn layer (the third metal layer 51c) which is a solid phase—liquid phase layer, where an alloy of the gold (Au) layer and the indium (In) layer is made, is formed.

The Ni layer (first metal layer 51a) forming the first metal layer 50a and the Ni layer (second metal layer 51b) forming the second metal layer 50b are solid phase—liquid phase bonded (TLP bonding: Transient Liquid Phase bonded) via the alloyed AuIn layer (third metal layer 51c), and thereby the metal layer 51 is formed. In this case, the gold (Au) layer is in the solid-phase and the indium (In) layer is in the liquid-phase. The melting point of the alloyed AuIn layer (third metal layer 51c) is approximately 400° C. through approximately 450° C. Therefore, the alloyed AuIn layer is not remelted at a temperature equal to or lower than the above-mentioned melting point of the alloyed AuIn layer (third metal layer 51c). Hence, high connecting reliability at the high temperature can be achieved.

In the case where the Ni/Pd/Au layer where nickel (Ni), palladium (Pd) and gold (Au) are stacked on the surface 33d in this order or the like is used as the second metal layer 50b, the Ni layer forming the first metal layer 50a and the Ni/Pd layer forming the second metal layer 50b are solid phase—liquid phase bonded (TLP bonding: Transient Liquid Phase bonded) via the AuIn layer where the Au layer and the In layer are alloyed, and thereby the metal layer 51 is formed. In this case, the metal layer 51 can be made thick.

Next, by performing the step the same as the step illustrated in FIG. 19 of the first embodiment, the wiring board 50 having the ceramic substrate 20 and the silicon substrate 30 illustrated in FIG. 20 is completed.

Thus, according to the second embodiment, the following effect in addition to the effect the same as that of the first embodiment can be achieved. In other words, since the solid phase—liquid phase bonding is used for bonding the ceramic substrate and the silicon substrate, the bonding temperature (approximately 180° C. through approximately 220° C.) can be made lower than the bonding temperature (approximately 280° C. through approximately 320° C.) in the case of eutectic bonding. In addition, the melting point of the alloy layer formed by the solid phase—liquid phase bonding is, for example, approximately 400° C. through approximately 450° C. Therefore, the alloy layer is not remelted at a temperature equal to or less than the above-mentioned melting point of the alloy layer. Hence, high connecting reliability at the high temperature can be achieved.

### Third Embodiment

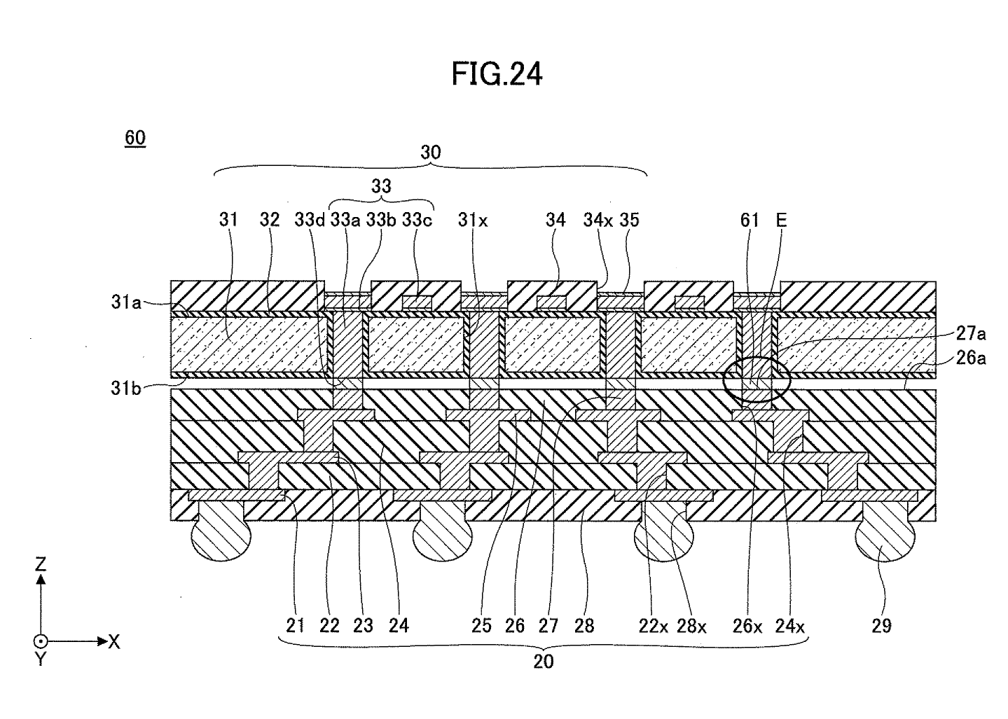

In the first embodiment, an example where the metal layer 41 of the wiring board 10 illustrated in FIG. 4 is formed by a eutectic reaction, which is one example of metal bonding, is discussed. In a third embodiment, an example where a metal layer 61 of a wiring board 60 illustrated in FIG. 24 is formed by bonding the same kinds of metal by heating and pressing (so-called, for example Cu—Cu bonding or the like), which is another example of the metal bonding, is discussed.

### Structure of Wiring Board of the Third Embodiment

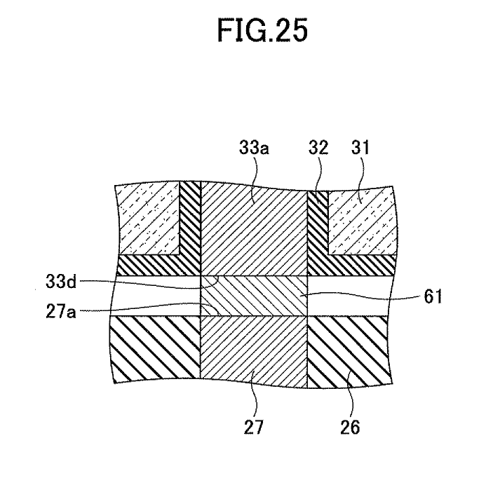

FIG. 24 is a cross-sectional view of an example of a wiring board of a third embodiment of the present invention. FIG. 25 is a cross-sectional view where an E-part in FIG. 24 is expanded. In FIG. 25, parts that are the same as the parts shown in FIG. 24 are given the same reference numerals, and explanation thereof is omitted. As shown in FIG. 24 and FIG. 25, a wiring board 60 is different from the wiring board 10 illustrated in FIG. 4 and FIG. 5 in that the metal layer 41 is replaced with a metal layer 61 in the wiring board 60.

In the wiring board 60, the metal layer 61 is a single layer including only a single kind of metal and is configured to connect the surface 27a of the electrode 27 of the ceramic substrate 20S and the surface 33d of the wiring layer 33 of the silicon substrate 30. The metal layer 61 can be, for example, a copper (Cu) layer. The metal layer 61 may be, for example, a gold (Au) layer or the like.

### Manufacturing Method of the Wiring Board of the Third Embodiment

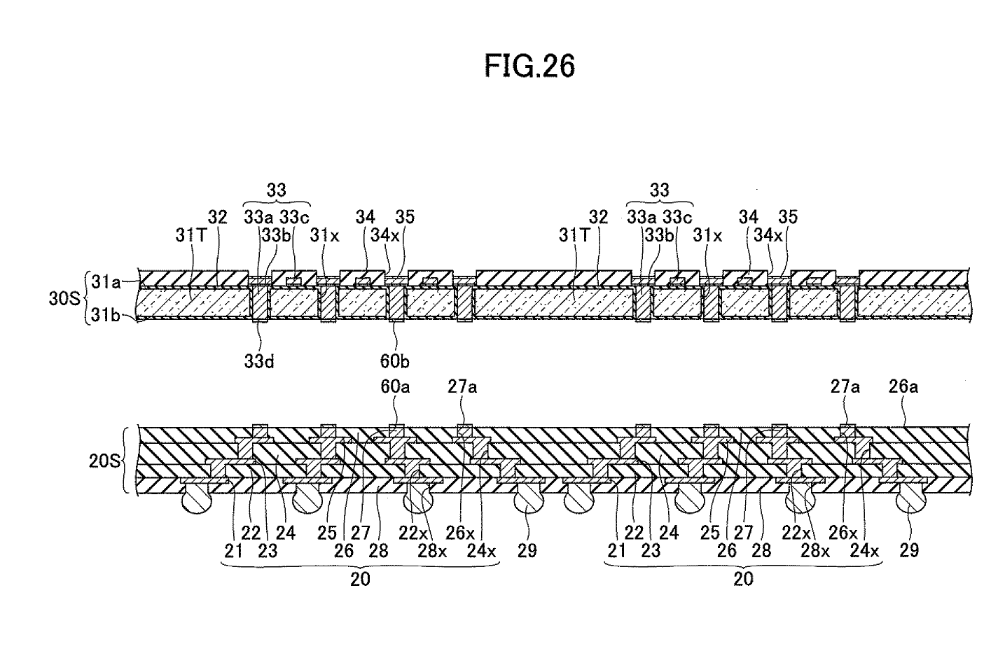

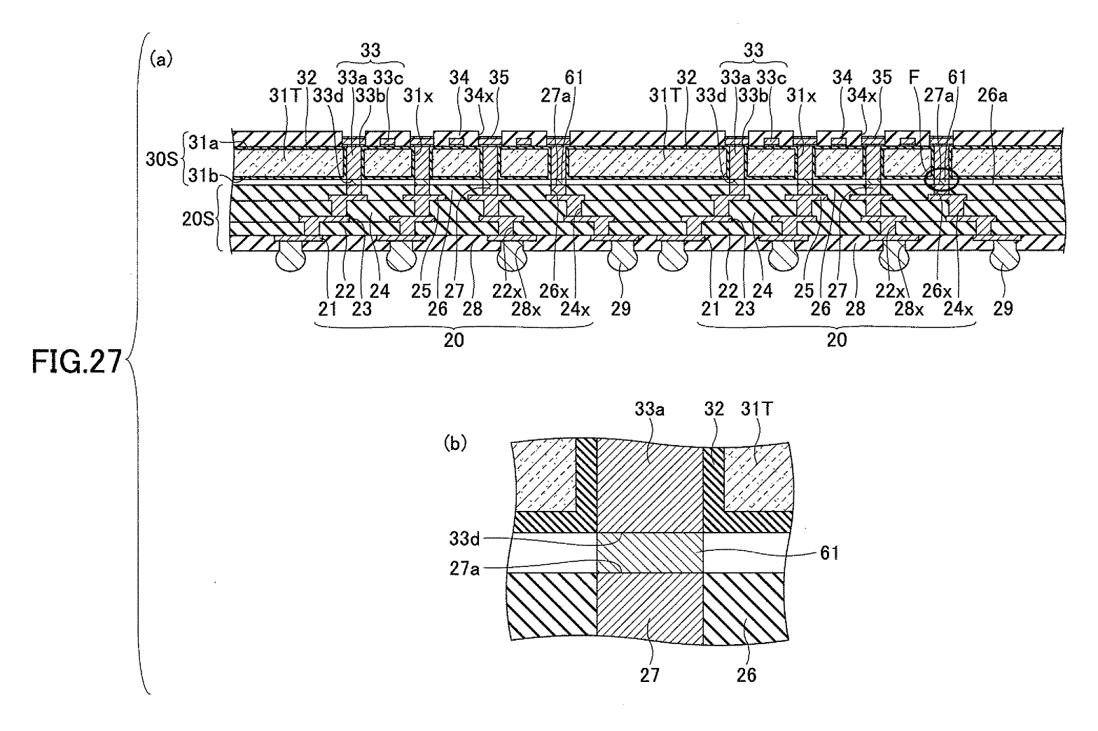

Next, a manufacturing method of the wiring board of the third embodiment is discussed with reference to FIG. 26 and FIG. 27.

FIG. 26 is a first view of an example of manufacturing steps of a wiring board of a third embodiment of the present invention. FIG. 27 is a second view of the example of the manufacturing steps of the wiring board of the third embodiment of the present invention. In FIG. 26 and FIG. 27, parts that are the same as the parts shown in FIG. 24 are given the same reference numerals, and explanation thereof is omitted.

First, the same steps as the steps illustrated in FIG. 6 through FIG. 16 of the first embodiment are performed. And then, in a step illustrated in FIG. 26, a first metal layer 60a is formed on the surfaces 27a of the electrodes 27 of the ceramic substrate 20S. In addition, a second metal layer 60b is formed on the surface 33d of the first metal layer 33a of the silicon substrate 30, namely a bottom surface of the first metal layer 33a supplied in the via-holes 31x.

Each of the first metal layer 60a and the second metal layer 60b may be, for example, a copper (Cu) layer. As long as the first metal layer 60a and the second metal layer 60b are layers made of the same kinds of metal, the first metal layer 60a and the second metal layer 60b may be, for example, a gold (Au) layer. The first metal layer 60a and the second metal layer 60b may be formed by, for example, an electroless plating method. Each of the thicknesses of the first metal layer 60a and the second metal layer 60b may be, for example, approximately 1 μm through approximately 5 μm. In this embodiment, an example where the copper (Cu) layer is used as the first metal layer 60a and the second metal layer 60b is discussed.

Next, in a step illustrated in FIGS. 27(a)-27(b), the first metal layer 60a formed on the surface 27a of the electrode 27 of the ceramic substrate 20S and the second metal layer 60b formed on the surface 33d of the first metal layer 33a of the silicon substrate 30 are bonded so that a metal layer 61 is formed (so-called Cu—Cu bonding). As a result of this, the ceramic substrate 20S and the silicon substrate 30S are bonded via the metal layer 61. FIG. 27(b) is an expanded cross-sectional view showing an F-part of FIG. 27(a).

More specifically, first, the center of the electrode 27 of the ceramic substrate 20S illustrated in FIG. 26 and the center of the via-hole 31x of the silicon substrate 30S are positioned and the first metal layer 60a and the second metal layer 60b come in contact with each other. Pressing at a pressure of, for example, approximately 100 MPa through approximately 400 MPa is applied. While the pressing is applied, the first metal layer 60a and the second metal layer 60b are heated at a temperature of approximately 300° C. through approximately 500° C.

As a result of this, the copper (Cu) layer forming the first metal layer 60a and the copper (Cu) layer forming the second metal layer 60b are not melted. Copper (Cu) atoms are diffused via an interface of both layers so that covalent bonding of the copper (Cu) layer forming the first metal layer 60a and the copper (Cu) layer forming the second metal layer 60b is made at the atomic level. As a result of this, a single copper (Cu) layer (metal layer 61) is newly formed. In other words, the surface 27a of the electrode 27 of the ceramic substrate 20S and the second metal layer 60b formed on the surface 33d of the first metal layer 33a of the silicon substrate 30 are bonded via the metal layer 61 formed by so-called Cu—Cu bonding of the first metal layer 60a and the second metal layer 60b. Since the metal layer 61 is formed by covalent bonding at the atomic level of the same kind of metal, the metal layer 61 has a high connecting reliability.

In a case where the same kind of the metal layer such as a gold (Au) layer is used as the first metal layer 60a and the second metal layer 60b, covalent bonding at the atomic level of each of the metal layers is made so that a single gold (Au) layer or the like is newly formed.

Next, by performing the step the same as the step illustrated in FIG. 19 of the first embodiment, the wiring board 60 having the ceramic substrate 20 and the silicon substrate 30 illustrated in FIG. 20 is completed.

Thus, according to the third embodiment, the following effect, in addition to the effect the same as that of the first embodiment can be achieved. In other words, a bonding (for example, so-called Cu—Cu bonding or the like) where the same kind of the metal is heated and pressed is applied as a bonding of the ceramic substrate and the silicon substrate. Therefore, the ceramic substrate and the silicon substrate can be bonded by using a layer where covalent bonding of the same kind of metal at the atomic level is made. Therefore, in this case compared to a case where eutectic bonding is used, the connecting reliability can be improved.

### Fourth Embodiment

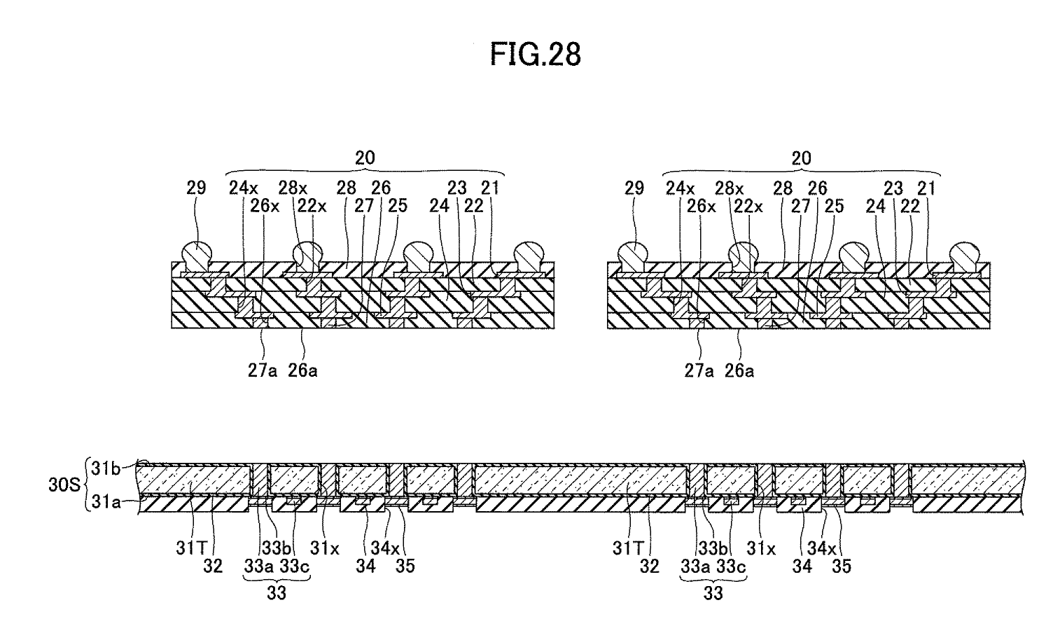

In a fourth embodiment, an example where the wiring board 10 illustrated in FIG. 4 is manufactured by a method different from the manufacturing method of the first embodiment is discussed with reference to FIG. 28 through FIG. 31. FIG. 28 through FIG. 31 are first through fourth views of an example of manufacturing steps of a wiring board of the fourth embodiment of the present invention. In FIG. 28 through FIG. 31, parts that are the same as the parts shown in FIG. 4 are given the same reference numerals, and explanation thereof is omitted.

First, in a step illustrated in FIG. 28, the silicon substrate 30S is manufactured by performing the same steps as the steps illustrated in FIG. 6 through FIG. 15 of the first embodiment. In addition, by performing the same steps as the step illustrated in FIG. 15, the ceramic substrate 20S is manufactured. The ceramic substrate 20S is made into pieces so that plural ceramic substrates 20 are formed. Although the external connecting terminals 29 are formed at each of the ceramic substrates 20, it is not always necessary to form the external connecting terminals 29 at this timing. The external connecting terminals 29 may be formed at a necessary timing. Here, FIG. 28 is a drawing inverted against (compared to) FIG. 15 and FIG. 16.

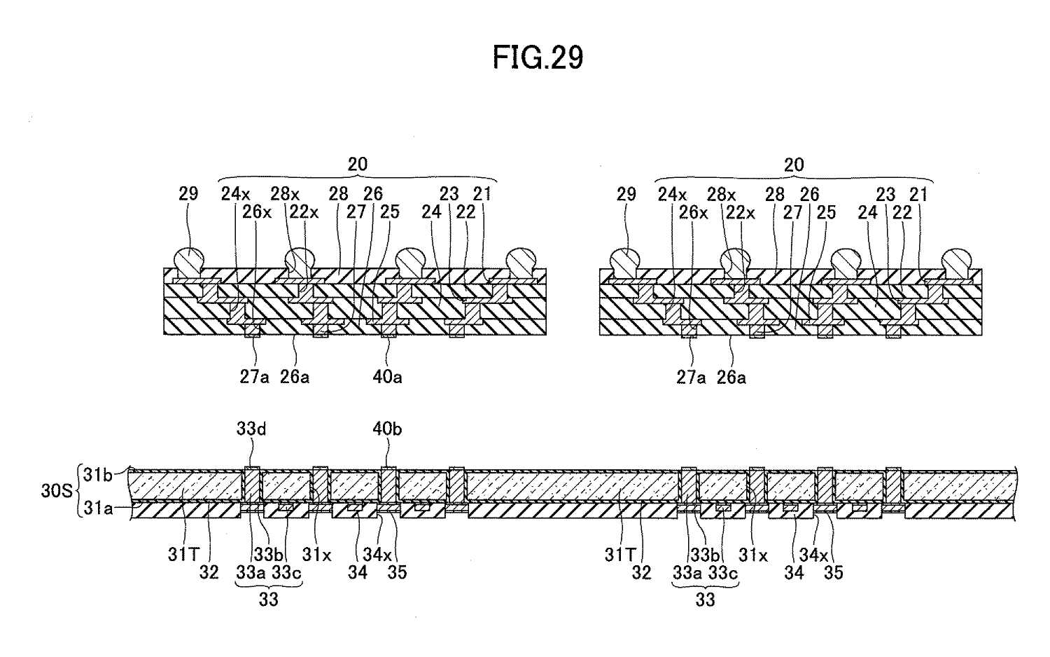

Next, in a step illustrated in FIG. 29, the first metal layer 40a is formed on the surfaces 27a of the electrodes 27 of the ceramic substrate 20. In addition, the second metal layer 40b is formed on the surface 33d of the first metal layer 33a of the silicon substrate 30.

The first metal layer 40a may be, for example, a Ni/Au layer where nickel (Ni) and gold (Au) are stacked on the surfaces 27a in this order. The second metal layer 40b can be, for example, a Ni/AuSn layer where nickel (Ni) and AuSn layers are stacked on the surface 33d in this order. The AuSn layer is a eutectic alloy layer which is made by eutectic reaction of gold (Au) and tin (Sn). The first metal layer 40a can be, for example, a Ni/SnAg layer where nickel (Ni) and SnAg layers are stacked on the surface 27a in this order. The SnAg layer is a eutectic alloy layer which is made by eutectic reaction of tin (Sn) and silver (Ag). The second metal layer 40b can be, for example, a Ni/SnAg layer where nickel (Ni) and SnAg layers are stacked on the surface 33d in this order. The SnAg layer is a eutectic alloy layer which is made by eutectic reaction of tin (Sn) and silver (Ag). The first metal layer 40a and the second metal layer 40b can be formed by, for example, an electroless plating method or the like. A thickness of each of the first metal layer 40a and the second metal layer 40b can be, for example, between approximately 1 μm and approximately 5 μm.

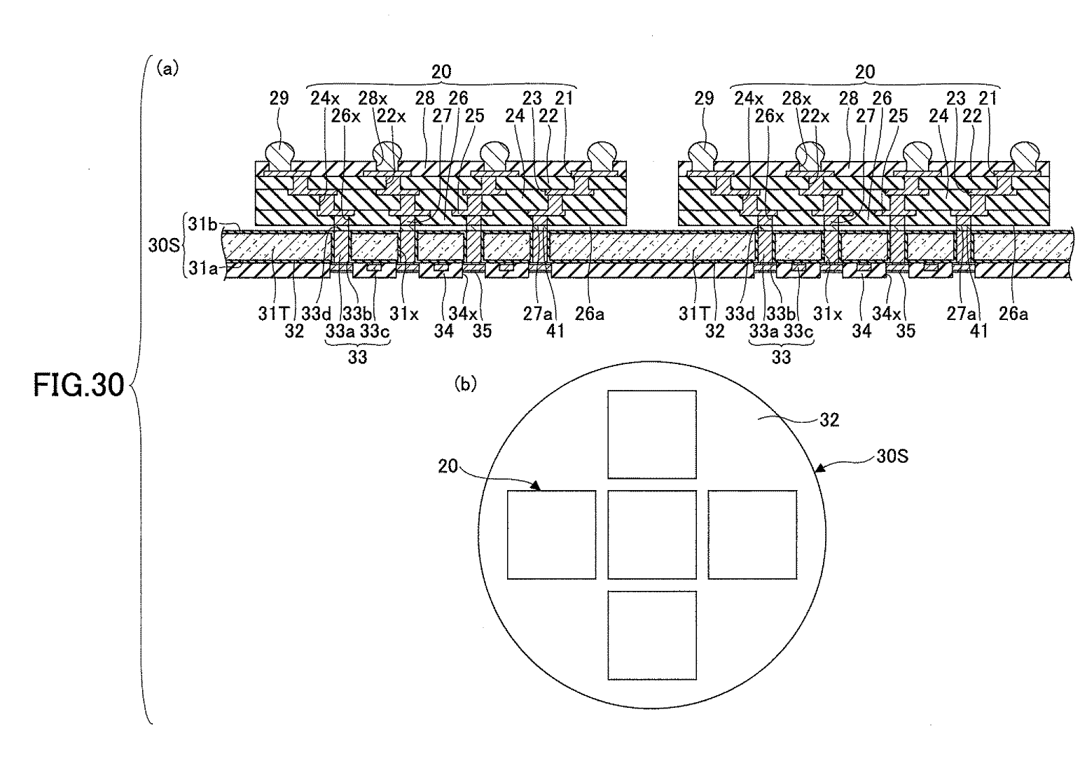

Next, in a step illustrated in FIGS. 30(a)-30(b), the first metal layer 40a formed on the surfaces 27a of the electrodes 27 of the ceramic substrate 20S and the second metal layer 40b formed on the surface 33d of the wiring layer 33 of the silicon substrate 30S are bonded so that the metal layer 41 is formed (eutectic bonding). As a result of this, each of the ceramic substrates 20 and the silicon substrate 30S are bonded to each other via the metal layer 41. Since details of the metal layer 41 are the same as details illustrated in FIG. 5, illustration thereof is omitted. FIG. 30(a) is a cross-sectional view and FIG. 30(b) is a plan view.

More specifically, first, the center of the electrode 27 of the ceramic substrate 20S illustrated in FIG. 29 and the center of the via-hole 31x of the silicon substrate 30S are positioned and the first metal layer 40a and the second metal layer 40b come in contact with each other. Pressing at a pressure of, for example, approximately 2 MPa through approximately 8 MPa is applied. While the pressing is applied, the first metal layer 40a and the second metal layer 40b are heated at a temperature of approximately 280° C. through approximately 320° C.

As a result of this, a eutectic reaction of gold (Au) and tin (Sn) is generated so that a new AuSn layer (hereinafter, a third metal layer 41c) is formed, where an Au layer forms the first metal layer 40a and an AuSn eutectic alloy layer forms the second metal layer 40b. After that, cooling is applied so that an Ni layer (hereinafter, a first metal layer 41a) forming the first metal layer 40a an Ni layer (hereinafter, a second metal layer 41b) forming the second metal layer 40b are eutectic-bonded via the newly formed AuSn layer (the third metal layer 41c). As a result of this, the metal layer 41 is formed.

In a case where the Ni/SnAg layer, where the nickel (Ni) layer and the SnAg layer being a eutectic alloy layer which is made by eutectic reaction of tin (Sn) and silver (Ag) are stacked on the surface 27a in this order, is used as the first metal layer 40a and the Ni/SnAg layer, where the nickel (Ni) layer and the SnAg layer being a eutectic alloy layer which is made by eutectic reaction of tin (Sn) and silver (Ag) are stacked on the surface 33d in this order, is used as the second metal layer 40b, by heating the first metal layer 40a and the second metal layer 40b at approximately 220° C. through approximately 280° C., a new SnAg layer is formed where a SnAg layer forming the first metal layer 40a and a SnAg layer forming the second metal layer 40b are a eutectic alloy based on the eutectic reaction. After that, cooling is applied so that the Ni layer forming the first metal layer 40a and the Ni layer forming the second metal layer 40b are eutectic-bonded via the newly formed SnAg layer. As a result of this, the metal layer 41 is formed.

Therefore, an electric characteristics inspection or the like of each of the ceramic substrates 20 is performed so as to determine a good or bad state in advance. By eutectic bonding only a good ceramic substrate 20 to the silicon substrate 30S, it is possible to increase the yield rate of the wiring board 10.

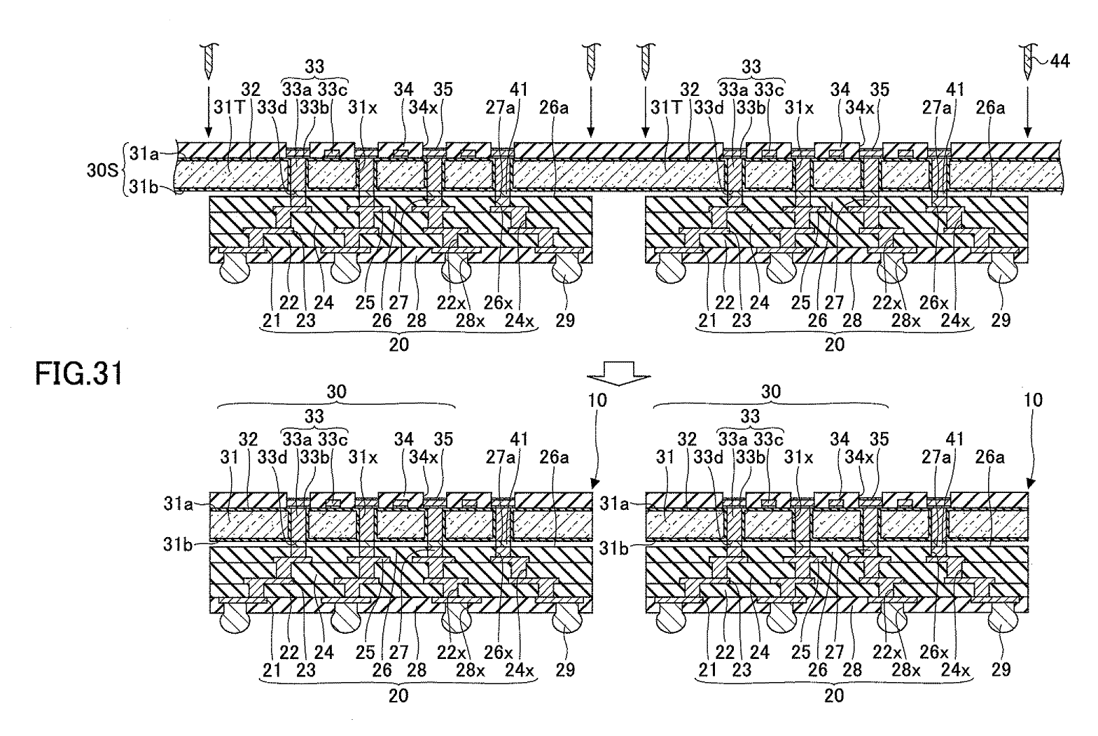

Next, in a step illustrated in FIG. 31, a structural body illustrated in FIG. 30 is cut in designated positions so that the wiring board 10 illustrated in FIG. 4 and including the ceramic substrate 20 and the silicon substrate 30 is completed. The structural body illustrated in FIG. 31 can be cut by dicing using the dicing blade 44 or the like. Here, “the designated positions” may be any position as long as each of the structural bodies can be made into pieces including the ceramic substrates 20, and may be, for example, external edge parts of the corresponding ceramic substrates 20.

As discussed above, according to the fourth embodiment of the present invention, the ceramic substrate and the silicon substrate are provided. The ceramic substrate includes stacked plural ceramic layers and internal wiring. An electrode electrically connected to the internal wiring is exposed from one surface of the ceramic substrate. The ceramic substrate is cut into plural pieces of the ceramic substrate. A first metal layer is formed on a surface of the electrode exposed from the one surface of each of the ceramic substrates. In addition, the silicon substrate includes a wiring layer. The wiring layer includes a wiring pattern formed on the main surface of the silicon substrate and via-fills. One end of the via-fill is electrically connected to the wiring pattern. Another end of the via-fill is exposed from a rear surface which is a surface opposite to a main surface. A second layer is formed on surfaces of the via-fills exposed from the rear surface of the silicon substrate. In addition, after the first metal layer of each of the separated ceramic substrates and the second metal layer of the unseparated silicon substrate are eutectically bonded to each other, the silicon substrate where the ceramic substrates are eutectically bonded is cut, and thereby the wiring boards where the electrodes of the ceramic substrate and the via-fills of the silicon substrate are electrically connected to each other are completed.

As a result of this, in addition to the effect the same as that of the first embodiment, the following effect can be achieved. In other words, plural separated ceramic substrates are eutectically bonded to the unseparated silicon substrate and then the silicon substrate is cut in the designated positions so that the wiring boards are completed. Therefore, an electric characteristics inspection or the like of each of the ceramic substrates 20 is performed so as to determine a good or bad state in advance. By eutectic bonding only a good ceramic substrate 20 to the silicon substrate 30S, it is possible to increase the yield rate of the wiring board 10.

### Fifth Embodiment

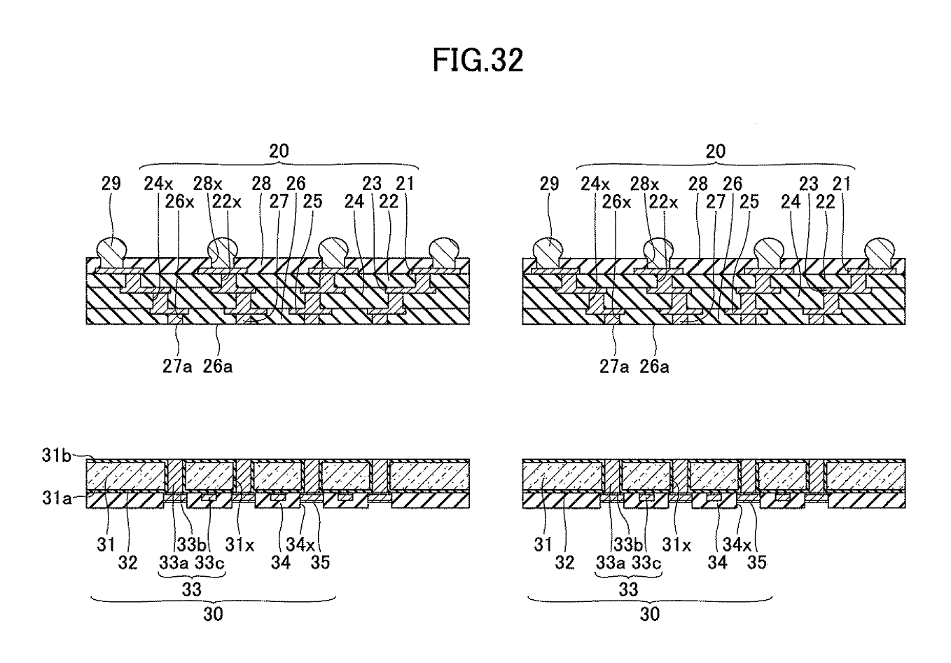

In a fifth embodiment, an example where the wiring board 10 illustrated in FIG. 4 is manufactured by a manufacturing method different from that of the first embodiment is discussed. FIG. 32 through FIG. 34 are first through third views of an example of manufacturing steps of a wiring board of the fifth embodiment of the present invention. In FIG. 32 through FIG. 34, parts that are the same as the parts shown in FIG. 4 are given the same reference numerals, and explanation thereof is omitted.

First, in a step illustrated in FIG. 32, the silicon substrate 30S is manufactured by performing the same steps as the steps illustrated in FIG. 6 through FIG. 15 of the first embodiment. The silicon substrate 30S is made into pieces so that plural silicon substrates 30 are formed. In addition, by performing the same step as the step illustrated in FIG. 16, the ceramic substrate 20S is manufactured. The ceramic substrate 20S is made into pieces so that plural ceramic substrates 20 are formed. Here, FIG. 32 is a drawing inverted against FIG. 15 and FIG. 16.

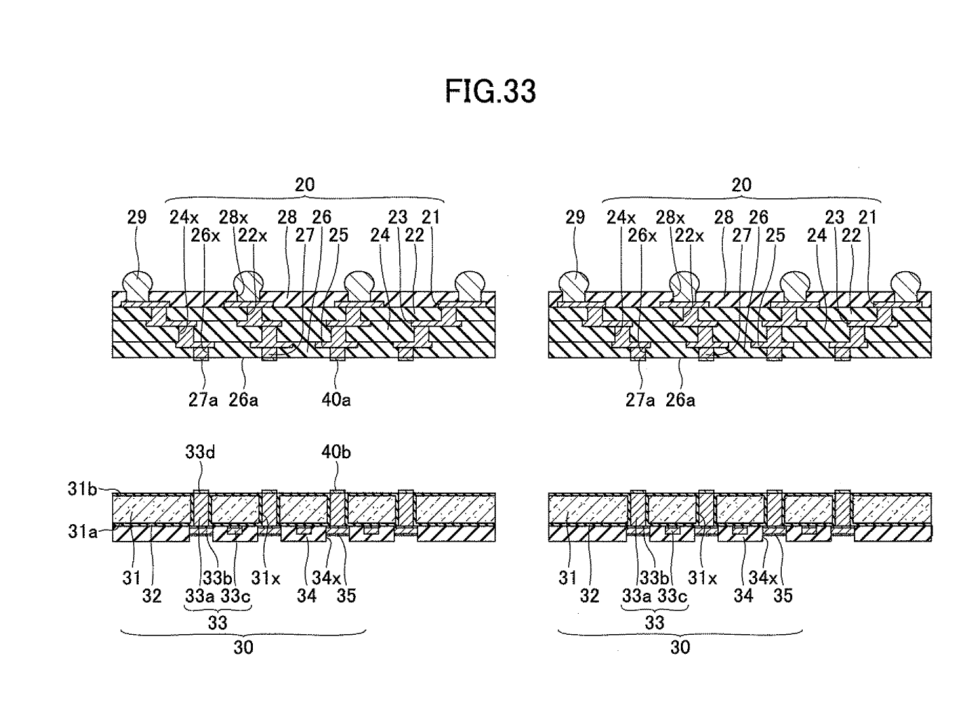

Next, in a step illustrated in FIG. 33, the first metal layer 40a is formed on the surfaces 27a of the electrodes 27 of the ceramic substrate 20. In addition, the second metal layer 40b is formed on the surface 33d of the first metal layer 33a of the silicon substrate 30.

The first metal layer 40a may be, for example, a Ni/Au layer where nickel (Ni) and gold (Au) are stacked on the surfaces 27a in this order. The second metal layer 40b can be, for example, a Ni/AuSn layer where nickel (Ni) and AuSn layers are stacked on the surface 33d in this order. The AuSn layer is a eutectic alloy layer which is made by eutectic reaction of gold (Au) and tin (Sn). The first metal layer 40a can be, for example, a Ni/SnAg layer where nickel (Ni) and SnAg layers are stacked on the surfaces 27a in this order. The SnAg layer is a eutectic alloy layer which is made by eutectic reaction of tin (Sn) and silver (Ag). The second metal layer 40b can be, for example, a Ni/SnAg layer where nickel (Ni) and SnAg layers are stacked on the surface 33d in this order. The SnAg layer is a eutectic alloy layer which is made by eutectic reaction of tin (Sn) and silver (Ag). The first metal layer 40a and the second metal layer 40b can be formed by, for example, an electroless plating method or the like. A thickness of each of the first metal layer 40a and the second metal layer 40b can be, for example, between approximately 1 μm and approximately 5 μm.

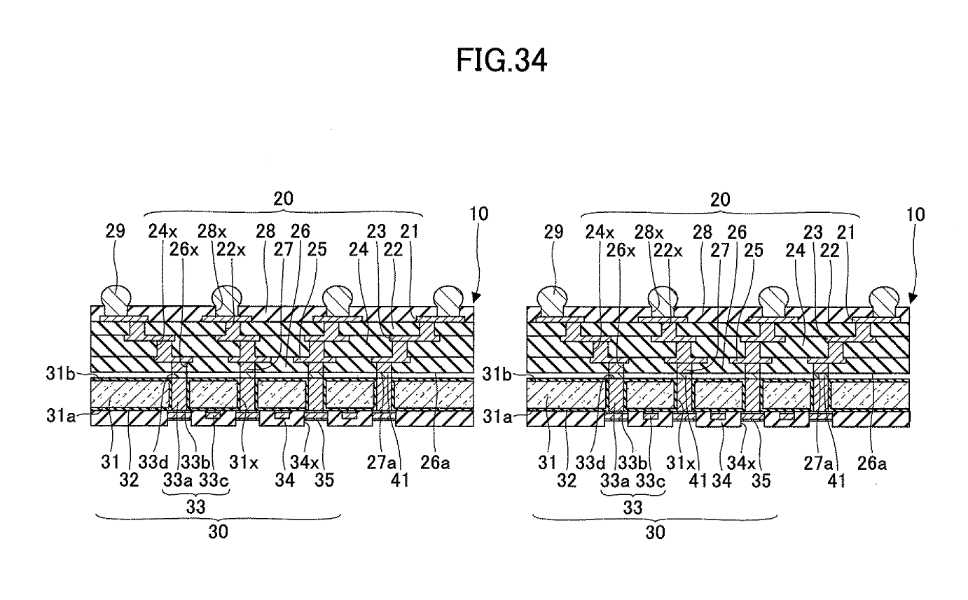

Next, in a step illustrated in FIG. 34, the first metal layer 40a formed on the surfaces 27a of the electrodes 27 of the ceramic substrate 20S and the second metal layer 40b formed on the surface 33d of the wiring layer 33 of the silicon substrate 30S are bonded so that the metal layer 41 is formed (eutectic bonding). As a result of this, the ceramic substrates 20 and the silicon substrate 30S are bonded to each other via the metal layer 41, so that the wiring boards 10 illustrated in FIG. 4 are completed. Since details of the metal layer 41 are the same as the details illustrated in FIG. 5, illustration thereof is omitted.

More specifically, first, the centers of the electrodes 27 of the ceramic substrate 20S illustrated in FIG. 33 and the corresponding centers of the via-holes 31x of the silicon substrate 30S are positioned and the first metal layer 40a and the second metal layer 40b come in contact with each other. Pressing at a pressure of, for example, approximately 2 MPa through approximately 8 MPa is applied. While the pressing is applied, the first metal layer 40a and the second metal layer 40b are heated at a temperature of approximately 280° C. through approximately 320° C.

As a result of this, eutectic reaction of gold (Au) and tin (Sn) is generated so that a new AuSn layer (hereinafter, a third metal layer 41c), where an Au layer forming the first metal layer 40a and an AuSn layer forming the second metal layer 40b are a eutectic alloy, is formed. After that, cooling is applied so that an Ni layer (hereinafter, a first metal layer 41a) forming the first metal layer 40a an Ni layer (hereinafter, a second metal layer 41b) forming the second metal layer 40b are eutectic-bonded via the newly formed AuSn layer (the third metal layer 41c). As a result of this, the metal layer 41 is formed.

In a case where the Ni/SnAg layer, where the nickel (Ni) layer and the SnAg layer being a eutectic alloy layer which is made by eutectic reaction of tin (Sn) and silver (Ag) are stacked on the surface 27a in this order, is used as the first metal layer 40a and the Ni/SnAg layer, where the nickel (Ni) layer and the SnAg layer being a eutectic alloy layer which is made by eutectic reaction of tin (Sn) and silver (Ag) are stacked on the surface 33d in this order, is used as the second metal layer 40b, by heating the first metal layer 40a and the second metal layer 40b at approximately 220° C. through approximately 280° C., a new SnAg layer, where a SnAg layer forming the first metal layer 40a and a SnAg layer forming the second metal layer 40b are a eutectic alloy based on the eutectic reaction, is formed. After that, cooling is applied so that the Ni layer forming the first metal layer 40a and the Ni layer forming the second metal layer 40b are eutectic-bonded via the newly formed SnAg layer. As a result of this, the metal layer 41 is formed.

Therefore, electric characteristics inspections or the like of each of the ceramic substrates 20 and each of the silicon substrates 30 are performed so as to determine a good or bad state in advance. By eutectic bonding only a good ceramic substrate 20 to a good silicon substrate 30, it is possible to increase the yield rate of the wiring board 10.

As discussed above, according to the fifth embodiment of the present invention, the ceramic substrate and the silicon substrate are provided. The ceramic substrate includes stacked plural ceramic layers and internal wiring. An electrode electrically connected to the internal wiring is exposed from one surface of the ceramic substrate. The ceramic substrate is cut into plural pieces of the ceramic substrate. A first metal layer is formed on a surface of the electrode exposed from the one surface of each of the ceramic substrates. In addition, the silicon substrate includes a wiring layer. The wiring layer includes a wiring pattern formed on the main surface of the silicon substrate and a via-fill. One end of the via-fill is electrically connected to the wiring pattern. Another end of the via-fill is exposed from a rear surface which is a surface opposite to a main surface. The silicon substrate is cut into plural pieces of the silicon substrate. A second layer is formed on a surface of the via-fill exposed from the rear surface of the pieced silicon substrate. In addition, the first metal layer of the separated ceramic substrates and the second metal layer of the corresponding separated silicon substrates are eutectically bonded to each other, and thereby the wiring boards where the electrodes of the ceramic substrate and the via-fills of the silicon substrate are electrically connected to each other are completed.

As a result of this, in addition to the effect the same as that of the first embodiment, the following effect can be achieved. In other words, plural separated ceramic substrates are eutectically bonded to the corresponding separated silicon substrates so that the wiring boards are completed. Therefore, electric characteristics inspections or the like of each of the ceramic substrates 20 and each of the silicon substrates 30 are performed so as to determine a good or bad state in advance. By eutectic bonding only a good ceramic substrate 20 to a good silicon substrate 30, it is possible to increase the yield rate of the wiring board 10.

Since plural separated ceramic substrates are eutectically bonded to the corresponding separated silicon substrates so that the wiring boards are completed, it is possible to perform a process of manufacturing the ceramic substrates and a process of manufacturing the silicon substrates in parallel. Therefore, it is possible achieve efficiency of the manufacturing steps.

### Sixth Embodiment

In a sixth embodiment of the present invention, an example of a semiconductor package where a semiconductor chip is mounted on the wiring board 10 (see FIG. 4) of the first embodiment is discussed. In the sixth embodiment, explanation of parts that are common with the first embodiment is omitted and parts different from the first embodiment are mainly discussed.

### Structure of Semiconductor Package of the Sixth Embodiment

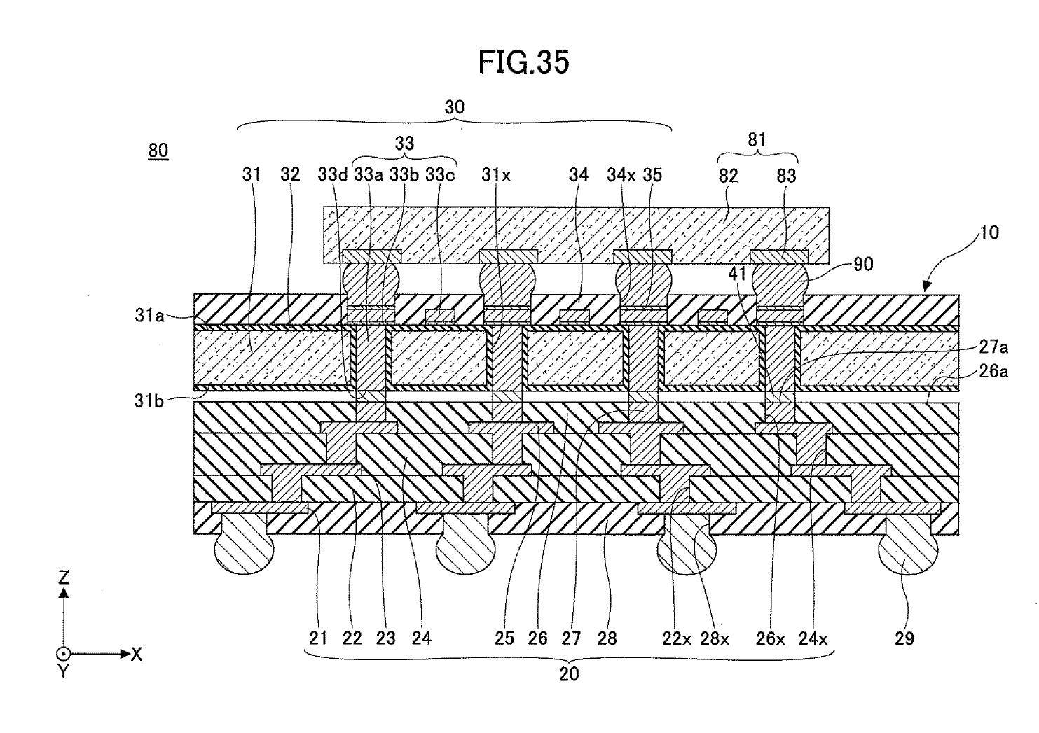

FIG. 35 is a cross-sectional view of an example of a wiring board of the sixth embodiment of the present invention. In FIG. 35, parts that are the same as the parts shown in FIG. 4 are given the same reference numerals, and explanation thereof is omitted. As shown in FIG. 35, a semiconductor package 80 illustrated in FIG. 4 includes a semiconductor chip 81 and solder bumps 90.

The semiconductor chip 81 includes a semiconductor substrate 82 and electrode pads 83. In the semiconductor substrate 82, a semiconductor integrated circuit (not illustrated in FIG. 33) is formed on a substrate made of, for example, silicon (Si), germanium (Ge), or the like. The electrode pads 83 are formed on one of surfaces of the semiconductor substrate 82 so as to be electrically connected to the semiconductor integrated circuit (not illustrated in FIG. 33). As a material of the electrode pads 83, for example, aluminum (Al) or the like can be used. Alternatively, as the material of the electrode pads 83, a material where copper (Cu) and aluminum (Al) are stacked in this order, a material where copper (Cu), aluminum (Al), and silicon (Si) are stacked in this order, or the like can be used.

The solder bumps 90 electrically connect the metal layer 35 of the wiring board 10 and the electrode pads 83 of the semiconductor chip 81. As a material of the solder bumps 90, for example, an alloy including Pb, an alloy of Sn and Cu, an alloy of Sn and Ag, an alloy of Sn, Ag, and Cu, or the like can be used.

### Manufacturing Method of the Wiring Board of the Sixth Embodiment

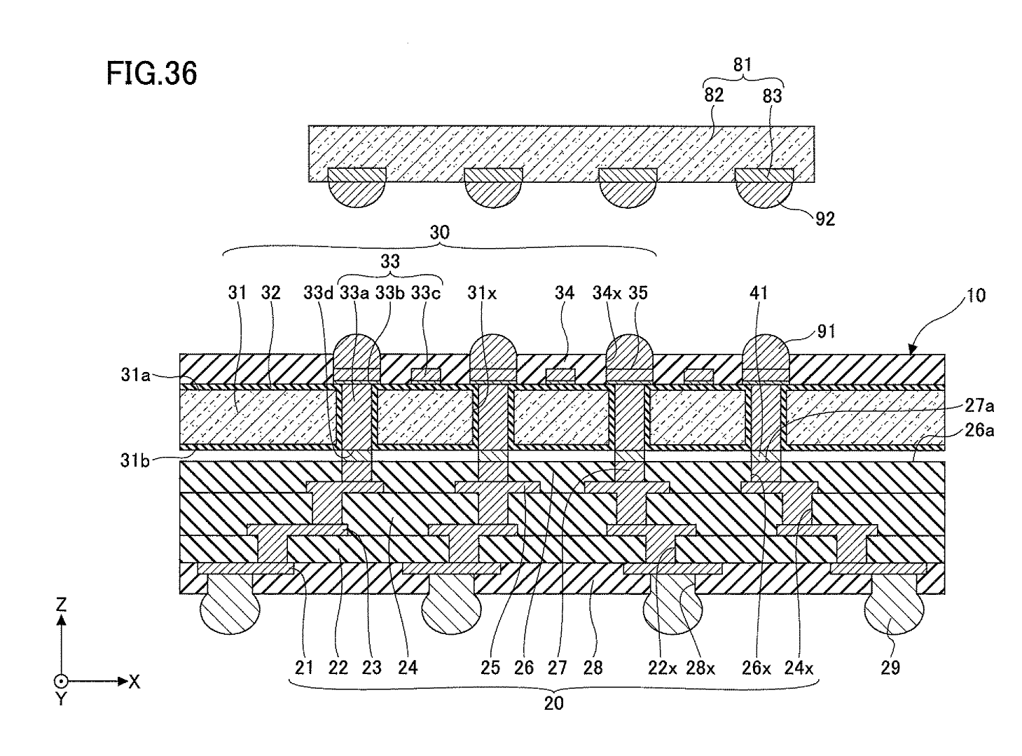

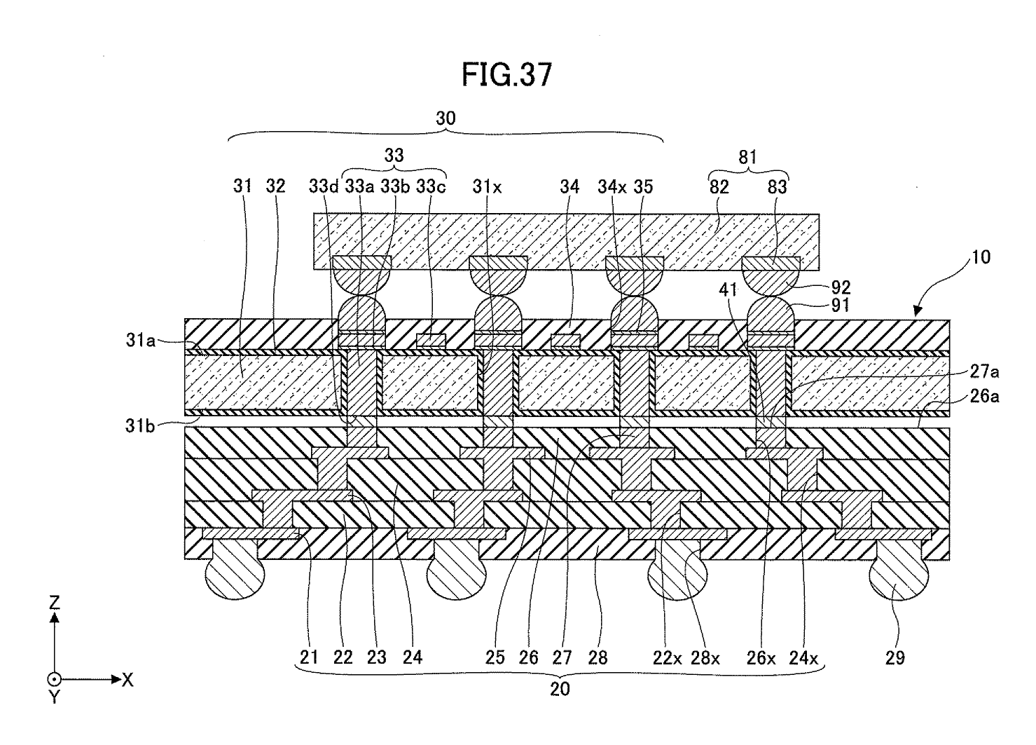

Next, a manufacturing method of the wiring board of the sixth embodiment is discussed with reference to FIG. 36 and FIG. 37. FIG. 36 and FIG. 37 are views of an example of manufacturing steps of the wiring board of the sixth embodiment of the present invention. In FIG. 36 and FIG. 37, parts that are the same as the parts shown in FIG. 35 are given the same reference numerals, and explanation thereof is omitted.

First, in a step illustrated in FIG. 36, the wiring board 10 is provided. Pre-solder 91 is formed on the metal layer 35. In addition, the semiconductor chip 81 is provided. Pre-solder 92 is formed on the electrode pads 83. The pre-solders 91 and 92 are formed by applying a solder paste made of an alloy including Pb, an alloy of Sn and Cu, an alloy of Sn and Ag, an alloy of Sn, Ag, and Cu, or the like on the metal layer 35 and the electrode pads 83 and performing a reflow process.

Next, in a step illustrated in FIG. 37, the metal layer 35 side of the wiring board 10 and the electrode pad 83 side of the semiconductor chip 81 are made to face each other so that the pre-solders 91 and 92 are positioned so as to face each other. Then, the pre-solders 91 and 92 are heated at, for example, approximately 230° C. so that the solder is melted and thereby the solder bumps 90 are formed. Thus, the semiconductor package 80 illustrated in FIG. 35 is completed.

Thus, according to the sixth embodiment of the present invention, the semiconductor package has the semiconductor chip mounted on the wiring board of the first embodiment via the connecting terminals. Here, in the case where the semiconductor chip to be mounted is made of silicon, the CTEs of the semiconductor chip and the silicon substrate forming the wiring board are substantially equal to each other. As a result of this, it is difficult to generate the thermal stress due to the difference of the CTEs at the connecting part of the semiconductor chip and the wiring board. Therefore, it is possible to improve connecting reliability between the wiring board and the semiconductor chip. In addition, since the connecting reliability between the wiring board and the semiconductor chip is improved, it is possible to eliminate a step of supplying the underfill resin between the semiconductor chip and the silicon substrate when the semiconductor package is manufactured.

In addition, since the ceramic substrate and the silicon substrate forming the wiring board are connected to each other by the metal layer, even if the CTE of the ceramic substrate is not equal to the CTE (approximately 3 ppm/° C.) of the silicon substrate, it is possible to secure the connecting reliability of the ceramic substrate and the silicon substrate. Therefore, it is possible to make a value of the CTE of the ceramic substrate close to the CTE (approximately 18 ppm/° C.) of the mounting board such as the motherboard mainly made of the resin board, such as between approximately 10 ppm/° C. and approximately 12 ppm/° C. Accordingly, when the semiconductor package of the sixth embodiment is connected to the mounting board such as the motherboard, it is difficult to generate thermal stress, due to differences of the CTEs, at the connecting part of the wiring board and the mounting board such as the motherboard. Therefore, it is possible to improve connection reliability of the connection between the wiring board and the mounting board such as the motherboard.

The CTE of the ceramic layer, among the ceramic layers forming the ceramic substrate, far from the silicon substrate can be close to the GTE of the mounting board such as the motherboard by making the CTE of the ceramic layer far from the silicon substrate greater than the CTE of the ceramic layer close to the silicon substrate. As a result of this, it is difficult to generate thermal stress, due to differences of the CTEs, at the connecting part of the wiring board and the mounting board such as the motherboard. Therefore, it is possible to improve connection reliability of the connection between the wiring board and the mounting board such as the motherboard.

### Modified Example 1 of the Sixth Embodiment

In a modified example 1 of the sixth embodiment, a modified example of the semiconductor package 80 (see FIG. 35) of the sixth embodiment is discussed. In the modified example 1 of the sixth embodiment, explanation of parts that are common with the sixth embodiment is omitted and parts different from the sixth embodiment are mainly discussed.

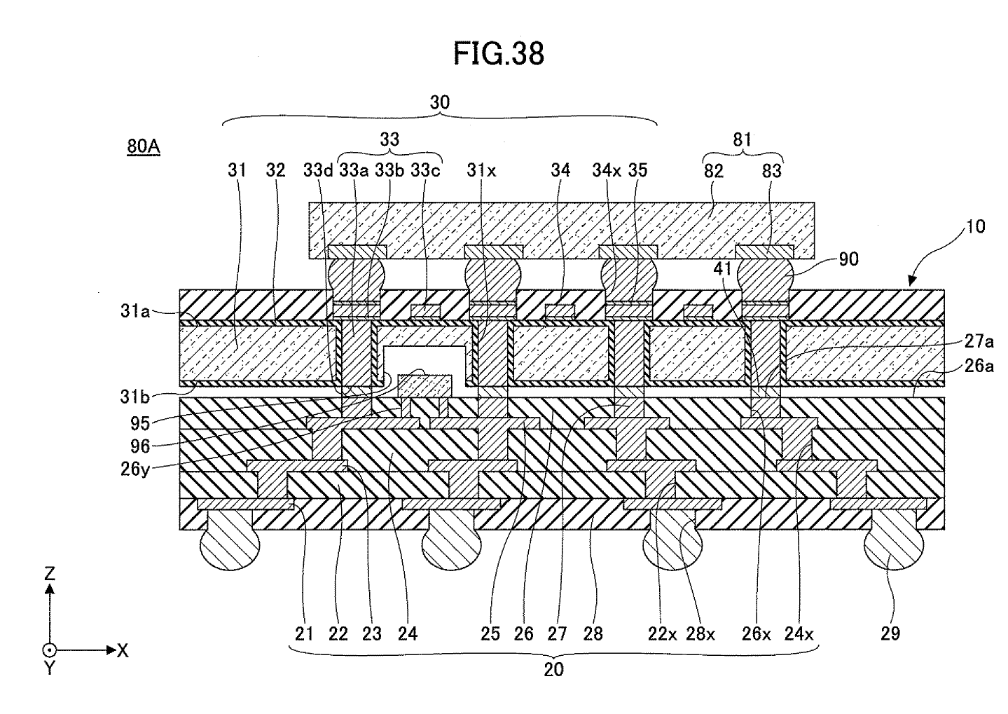

FIG. 38 is a cross-sectional view of the first modified example of a wiring board of the sixth embodiment of the present invention. In FIG. 38, parts that are the same as the parts shown in FIG. 35 are given the same reference numerals, and explanation thereof is omitted. As shown in FIG. 38, in a semiconductor package 80A, a cavity part 95 is provided in the silicon substrate 30 of the wiring board 10. A MEMS (Micro Electro Mechanical Systems) device 96 is provided in the cavity part 95.

The cavity part 95 can be formed in the silicon substrate 30 by an anisotropic etching method such as the DRIE (Deep Reactive Ion Etching) method using, for example, SF₆, before the silicon substrate 30 and the ceramic substrate 20 are metal bonded. The MEMS device 96 is electrically connected to the third wiring layer 25 by the via-fill supplied in the fourth via-holes 26y. The MEMS device 96 can be mounted on the ceramic substrate 20 before the silicon substrate 30 and the ceramic substrate 20 are metal bonded. As an example of the MEMS device 96, for example, a pressure sensor or an acceleration sensor can be used. The semiconductor chip 81 is configured to control the MEMS device 96.

As a result of this, although this embodiment can achieve the same effect as that of the sixth embodiment, the following can be further achieved. In other words, the cavity part is provided in the silicon substrate of the wiring board. The MEMS device is provided in the cavity part. The semiconductor chip is configured to control the MEMS device provided in the wiring board. Hence, it is possible to realize the semiconductor package having the MEMS device, the semiconductor package being where the control of the MEMS device can be performed.

### Modified Example 2 of the Sixth Embodiment

In a modified example 2 of the sixth embodiment, another modified example of the semiconductor package 80 (see FIG. 35) of the sixth embodiment is discussed. In the modified example 2 of the sixth embodiment, explanation of parts that are common with the sixth embodiment is omitted and parts different from the sixth embodiment are mainly discussed.

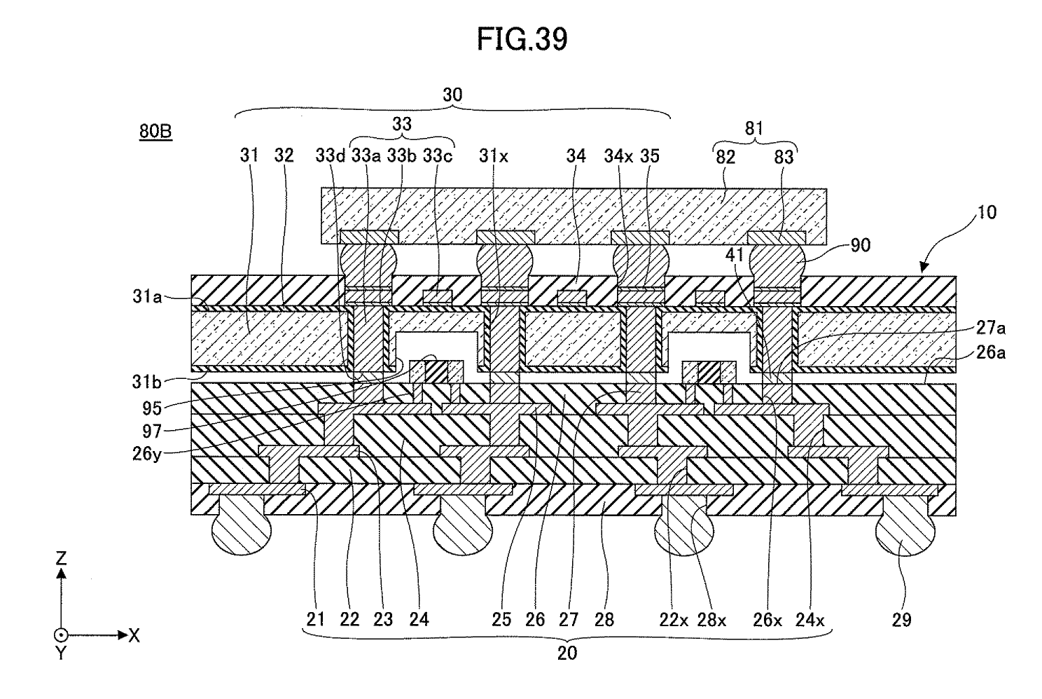

FIG. 39 is a cross-sectional view of the second modified example of a wiring board of the sixth embodiment of the present invention. In FIG. 39, parts that are the same as the parts shown in FIG. 35 are given the same reference numerals, and explanation thereof is omitted. As shown in FIG. 39, in a semiconductor package 80B, a cavity part 95 is provided in the silicon substrate 30 of the wiring board 10. A capacitor (chip capacitor) 97 is provided in the cavity part 95.

The cavity part 95 can be formed in the silicon substrate 30 by an anisotropic etching method such as the DRIE (Deep Reactive Ion Etching) method using, for example, SF₆, before the substrate main body 31 and the ceramic substrate 20 are metal bonded. The capacitor 97 is electrically connected to the third wiring layer 25 by the via-fill supplied in the fourth via-holes 26y. The capacitor may be provided right under the semiconductor chip 81. The capacitor 97 can be mounted on the ceramic substrate 20 before the silicon substrate 30 and the ceramic substrate 20 are metal bonded.

According to the modified example 2 of the sixth embodiment, although this embodiment can achieve the same effect as that of the first embodiment, the following can be further achieved. In other words, the cavity part is provided in the silicon substrate of the wiring board. The capacitor is provided in the cavity part. Hence, it is possible to provide the capacitor right under the semiconductor chip, and therefore the electric characteristics of the semiconductor package can be improved. In the cavity part 95, not only the capacitor (chip capacitor) but also various kinds of the electronic components such as a resistor or inductor can be mounted.

### Modified Example 3 of the Sixth Embodiment

In a modified example 3 of the sixth embodiment, another modified example of the semiconductor package 80 (see FIG. 33) of the sixth embodiment is discussed. In the modified example 3 of the sixth embodiment, explanation of parts that are common with the sixth embodiment is omitted and parts different from the sixth embodiment are mainly discussed.

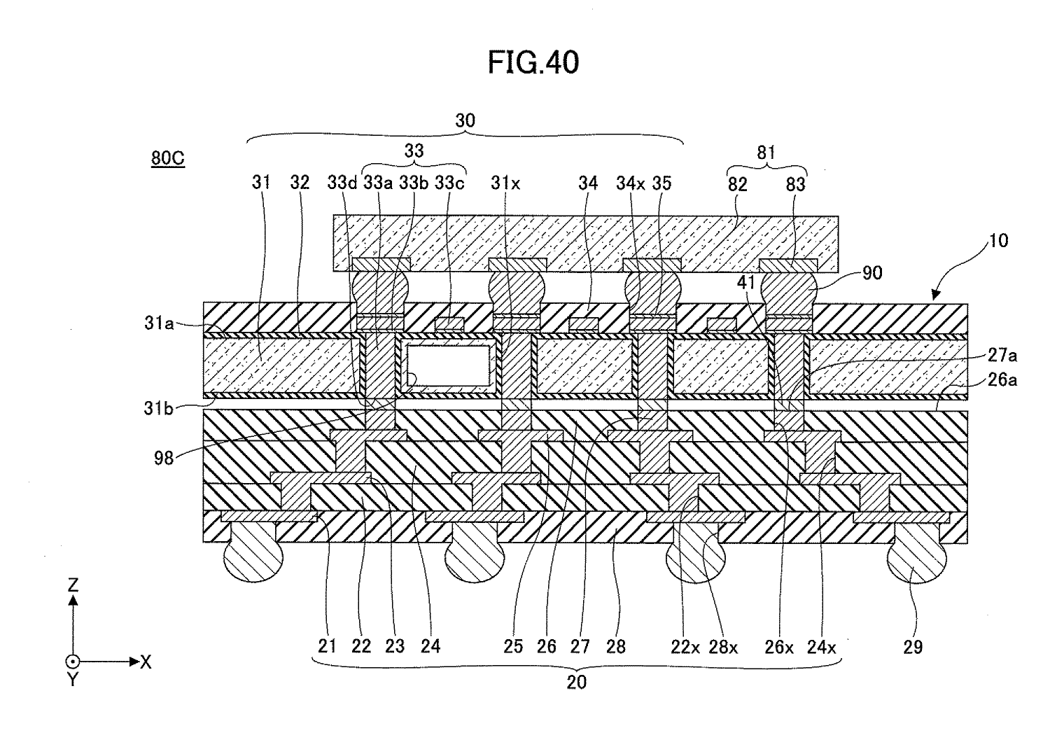

FIG. 40 is a cross-sectional view of the third modified example of a wiring board of the sixth embodiment of the present invention. In FIG. 40, parts that are the same as the parts shown in FIG. 35 are given the same reference numerals, and explanation thereof is omitted. As shown in FIG. 40, in a semiconductor package 80C, a cavity part 98 is provided in the silicon substrate 30 of the wiring board 10. The cavity part 95 is used as a coolant flow path where a coolant such as water is supplied.

The cavity part 95 can be formed in the silicon substrate 30 by an anisotropic etching method such as the DRIE (Deep Reactive Ion Etching) method using, for example, SF₆, before the silicon substrate 30 and the ceramic substrate 20 are metal bonded. The cavity part 98 may be provided right under the semiconductor chip 81.

According to the modified example 3 of the sixth embodiment, although this embodiment can achieve the same effect as that of the sixth embodiment, the following can be further achieved. In other words, the cavity part is provided in the silicon substrate of the wiring board. The cavity part is used as a coolant flow path where a coolant such as water is supplied. Hence, it is possible to provide the coolant flow path right under the semiconductor chip, and therefore to improve heat dissipation capabilities of the semiconductor package.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention. Although the embodiments of the present invention have been described in detail, it should be understood that the various changes, substitutions, and alterations could be made hereto without departing from the spirit and scope of the invention.

For example, instead of the above-discussed method (so-called “via first”), the following method (so-called “via last”) may be applied for manufacturing the silicon substrate. In other words, the thermal oxidization film is formed on a surface of the silicon wafer or the like and then the wiring layer is formed on the thermal oxidization film by a semi-additive method. After that, a piercing hole is formed in a position corresponding to the wiring layer from the rear surface of the silicon wafer or the like by a dry etching method or the like. After the thermal oxidization film is formed on the internal surface of the piercing hole and the rear surface of the silicon wafer or the like, the conductive material is supplied in the piercing hole so as to be conductively connected to the wiring layer.

Furthermore, in the fourth through sixth embodiments and modified examples thereof, the wiring board 50 or the wiring board 60, instead of the wiring board 10, may be used.

What is claimed is:

1. A wiring board, comprising:
a ceramic substrate including a plurality of stacked ceramic layers, an internal wiring, and an electrode electrically connected to the internal wiring, the electrode being exposed from a first surface of the ceramic substrate; and
a silicon substrate including a wiring layer, the wiring layer including a wiring pattern and a via-fill, the wiring pattern being formed on a main surface of the silicon substrate, an end of the via-fill being electrically connected to the wiring pattern, another end of the via-fill being exposed from a rear surface of the silicon substrate positioned opposite to the main surface,
wherein the another end of the via-fill is bonded to the electrode of the ceramic substrate via a metal layer.

2. The wiring board as claimed in claim 1,
wherein each of the ceramic layers includes alumina cordierite.

3. The wiring board as claimed in claim 2,
wherein the ceramic layers include different amounts of the alumina cordierite.

4. The wiring board as claimed in claim 1,
wherein a coefficient of thermal expansion of the ceramic layer far from the silicon substrate is greater than the coefficient of thermal expansion of the ceramic layer close to the silicon substrate.

5. The wiring board as claimed in claim 1,
wherein the metal layer includes a eutectic alloy layer.

6. The wiring board as claimed in claim 1,
wherein the metal layer includes a solid phase-liquid phase alloy layer.

7. The wiring board as claimed in claim 1,
wherein the metal layer includes a single kind of metal.

8. The wiring board as claimed in claim 1,
wherein a cavity part is formed at the rear surface of the silicon substrate.

9. The wiring board as claimed in claim 8,
wherein the cavity part is configured to expose the first surface of the ceramic substrate; and
a MEMS device is mounted on the first surface of the ceramic substrate in the cavity part.

10. The wiring board as claimed in claim 8,
wherein the cavity part is configured to expose the first surface of the ceramic substrate; and
a capacitor is mounted on the first surface of the ceramic substrate in the cavity part.

11. The wiring board as claimed in claim 8,
wherein the cavity part is a coolant flow path where a coolant is supplied.

12. A manufacturing method of a wiring board, comprising:
a first step of forming a first metal layer on a first surface of a ceramic substrate, the ceramic substrate having a plurality of stacked ceramic layers, an internal wiring, and an electrode electrically connected to the internal wiring, the electrode exposed from the first surface of the ceramic substrate;
a second step of forming a second metal layer at a silicon substrate, the silicon substrate including a wiring layer, the wiring layer including a wiring pattern and a via-fill, the wiring pattern being formed on a main surface of the silicon substrate, an end of the via-fill being electrically connected to the wiring pattern, another end of the via-fill being exposed from a rear surface of the silicon substrate positioned opposite to the main surface, the second metal layer being formed on the another end of the via-fill; and
a third step of electrically connecting the electrode and the another end of the via-fill by bonding the first metal layer and the second metal layer.

13. The manufacturing method of the wiring board as claimed in claim 12,
wherein, in the first step, a plurality of the ceramic substrates is provided, and the first metal layer is formed on the surfaces of the electrodes exposed from the first surfaces of the ceramic substrates;
in the second step, a first substrate, instead of the silicon substrate, having plural areas which become the silicon substrates by cutting the first substrate into pieces, is provided, and the second metal layer is formed on the another ends of the via-fills exposed from the rear surface of the first substrate in the plural areas of the first substrate;
in the third step, the first metal layers formed at the ceramic substrates and the second metal layer formed in the corresponding plural areas of the first substrate are bonded so that the electrodes and the corresponding via-fills are electrically connected to each other; and
after the third step, a structural body, where the ceramic substrates are bonded to the corresponding plural areas of the first substrate, is cut in the plural areas so that pieces are made, and thereby a plurality of the wiring boards, where the electrodes and the corresponding via-fills are electrically connected to each other, is formed.

14. The manufacturing method of the wiring board as claimed in claim 12,
wherein, in the first step, a second substrate, instead of the ceramic substrate, having plural areas which become the ceramic substrates by cutting the second substrate into pieces, is provided, and the first metal layer is formed on the surfaces of the electrodes exposed from the first surface of the second substrate in the plural areas of the second substrate;
in the second step, a first substrate, instead of the silicon substrate, having plural areas which become the silicon substrates by cutting the first substrate into pieces, is provided, and the second metal layer is formed on the another ends of the via-fills exposed from the rear surface of the first substrate in the plural areas of the first substrate;
in the third step, the first metal layer formed in the plural areas of the second substrate and the second metal layer formed in the corresponding plural areas of the first substrate are bonded so that the electrodes and the corresponding via-fills are electrically connected to each other; and
after the third step, a structural body, where the second substrate is bonded to the first substrate, is cut in the plural areas so that pieces are made, and thereby a plurality of the wiring boards, where the electrodes and the corresponding via-fills are electrically connected to each other, is formed.

15. The manufacturing method of the wiring board as claimed in claim 12,
wherein the third step includes a step of heating the first metal layer and the second metal layer at a temperature where a eutectic reaction is generated between at least a part of metal included in the first metal and at least a part of metal included in the second metal, so that a eutectic alloy layer, made of an alloy of the metal where the eutectic reaction is generated, is formed.

16. The manufacturing method of the wiring board as claimed in claim 12,
wherein the third step includes a step of heating the first metal layer and the second metal layer at a temperature
where at least a part of metal included in at least one of the first metal layer and the second metal layer becomes liquid-phase and another part of the metal is in solid-phase, so that a solid phase-liquid phase alloy layer, made of an alloy of the liquid-phase metal and the solid-phase metal, is formed.

17. The manufacturing method of the wiring board as claimed in claim 12,
wherein the third step includes a step of heating and pressing the first metal layer and the second metal layer made of the same kind of metal, so that a single metal layer, formed by covalent bonding in an atom level of the same kind of metal forming the first metal layer and the second metal layer, is formed.

18. A semiconductor package, comprising
the wiring board as claimed in claim 1; and
a semiconductor chip mounted on the main surface of the silicon substrate of the wiring board.
